(19) United States
(12) Patent Application Publication
(10) Pub. No.: US 2006/0255310 A1
(43) Pub. Date: Nov. 16, 2006

(54) Composite oxide having n-type thermoelectric characteristics

(76) Inventor: Ryoji Funahashi, Osaka (JP)

Correspondence Address: KNOBBE MARTENS OLSON & BEAR LLP, 2040 MAIN STREET, FOURTEENTH FLOOR, IRVINE, CA, 92614, US

(21) Appl. No.: 10/550,670

(22) PCT Filed: Mar. 24, 2004
(86) PCT No.: PCT/JP04/04034

§ 371 Date: Sep. 26, 2005

(30) Foreign Application Priority Data
Mar. 26, 2003 (JP) 2003-086006

(51) Int. Cl. C04B 35/00; H01L 29/12; H01L 35/12

(52) U.S. Cl. 252/62.3 T; 136/236.1

(57) ABSTRACT

The present invention provides a complex oxide having a composition represented by the formula Ln₁₋ₓMₓNiO_{y}; wherein Ln is a lanthanide, M is at least one element selected from the group consisting of Na, K, Li, Zn, Pb, Ba, Ca, Al, Bi, and rare earth elements being not the same as Ln; and 0≦x≦0.8; and 2.7≦y≦3.3, or the formula (Ln₁₋ₓMₓ)₂NiO_{y}; wherein Ln is a lanthanide, M is at least one element selected from the group consisting of Na, K, Li, Zn, Pb, Ba, Ca, Al, Bi, and rare earth elements being not the same as Ln; 0≦x≦0.8; and 3.6≦y≦4.4, the complex oxide having a negative Seebeck coefficient at 100° C. or higher. The complex oxide of the invention has a negative Seebeck coefficient and low electrical resistivity and also has excellent heat resistance, chemical durability, etc., and thus can be effectively utilized as an n-type thermoelectric material in air at high temperatures.

### TECHNICAL FIELD

The present invention relates to a complex oxide capable of achieving high performance as an n-type thermoelectric material, and an n-type thermoelectric material using the complex oxide.

### BACKGROUND ART

In Japan, only 30% of the primary energy supply is used as effective energy, with about 70% being eventually lost to the atmosphere as heat. The heat generated by combustion in industrial plants, garbage-incineration facilities or the like is lost to the atmosphere without conversion into other energy. In this way, a vast amount of thermal energy is wastefully discarded, while acquiring only a small amount of energy by combustion of fossil fuels or other means.

To increase the proportion of energy to be utilized, the thermal energy currently lost to the atmosphere should be effectively used. For this purpose, thermoelectric conversion, which directly converts thermal energy to electrical energy, is an effective means. Thermoelectric conversion, which utilizes the Seebeck effect, is an energy conversion method for generating electricity by creating a difference in temperature between both ends of a thermoelectric material to produce a difference in electric potential. In such a method for generating electricity utilizing thermoelectric conversion, i.e., thermoelectric generation, electricity is generated simply by setting one end of a thermoelectric material at a location heated to a high temperature by waste heat, and the other end in the atmosphere (room temperature) and connecting conductive wires to both ends. This method entirely eliminates the need for moving parts such as the motors or turbines generally required for electric power generation. As a consequence, the method is economical and can be carried out without generating gases by combustion. Moreover, the method can continuously generate electricity until the thermoelectric material has deteriorated.

Therefore, thermoelectric generation is expected to play a role in the resolution of future energy problems. To realize thermoelectric generation, large amounts of a thermoelectric material that has a high thermoelectric conversion efficiency and excellent heat resistance, chemical durability, etc. will be required.

CoO₂-based layered oxides such as Ca₃Co₄O₉ have been reported as substances that achieve excellent thermoelectric performance in air at high temperatures. However, all such oxides have p-type thermoelectric properties, and are materials with a positive Seebeck coefficient, i.e., materials in which the portion located at the high-temperature side has a low electric potential.

To produce a thermoelectric module using thermoelectric conversion, usually not only a p-type thermoelectric material but also an n-type thermoelectric material are needed. However, n-type thermoelectric materials that have excellent heat resistance, chemical durability, etc., and have a high thermoelectric conversion efficiency have not yet been found. Therefore, thermoelectric generation using waste heat has not yet become practical.

In such circumstances, the development of n-type thermoelectric materials is greatly desired that are composed of low toxic and abundantly available elements, have excellent heat resistance, chemical durability, etc., and have a high thermoelectric conversion efficiency.

### BRIEF DESCRIPTION OF THE DRAWINGS

FIG. 1 shows X-ray diffraction patterns of the complex oxides obtained in Examples 1 and 541.

FIG. 2 schematically shows the crystal structures of complex oxides 1 and 2.

FIG. 3 is a view schematically showing a thermoelectric module comprising the complex oxide of the invention as a thermoelectric material.

FIG. 4 is a graph showing the temperature dependency of the Seebeck coefficient of the sintered complex oxides prepared in Examples 1 and 541.

FIG. 5 is a graph showing the temperature dependency of the electrical resistivity of the sintered complex oxides prepared in Examples 1 and 541.

### DISCLOSURE OF THE INVENTION

The present invention has been made to solve the above problems. A principal object of the invention is to provide a novel material that achieves excellent performance as an n-type thermoelectric material.

The present inventors conducted extensive research to achieve the above object and found that a complex oxide having a specific composition comprising a lanthanide, Ni and O as essential elements and partially substituted by specific elements has a negative Seebeck coefficient and a low electrical resistivity, thus possessing excellent properties as an n-type thermoelectric material. The invention has been accomplished based on this finding.

The present invention provides the following complex oxides and n-type thermoelectric materials using the complex oxides.

1. A complex oxide having a composition represented by the formula Ln₁₋ₓMₓNiO_{y}; wherein Ln is a lanthanide, M is at least one element selected from the group consisting of Na, K, Li, Zn, Pb, Ba, Ca, Al, Bi, and rare earth elements being not the same as Ln; and O≦x≦0.8; and 2.7≦y≦3.3, the complex oxide having a negative Seebeck coefficient at 100° C. or higher.

2. A complex oxide having a composition represented by the formula Ln₁₋ₓMₓNiO_{y}; wherein Ln is a lanthanide, M is at least one element selected from the group consisting of Na, K, Li, Zn, Pb, Ba, Ca, Al, Bi, and rare earth elements being not the same as Ln; 0≦x≦0.8; and 2.7≦y≦3.3, the complex oxide having an electrical resistivity of 1 Ωcm or less at 100° C. or higher.

3. A complex oxide having a composition represented by the formula (Ln₁₋ₓMₓ)₂NiO_{y}; wherein Ln is a lanthanide, M is at least one element selected from the group consisting of Na, K, Li, Zn, Pb, Ba, Ca, Al, Bi, and rare earth elements being not the same as Ln; 0≦x≦0.8; and 3.6≦y≦4.4, the complex oxide having a negative Seebeck coefficient at 100° C. or higher.

4. A complex oxide having a composition represented by the formula (Ln₁₋ₓMₓ)₂NiO_{y}; wherein Ln is a lanthanide, M is at least one element selected from the group consisting of Na, K, Li, Zn, Pb, Ba, Ca, Al, Bi, and rare earth elements being not the same as Ln; 0≦x≦0.8, and 3.6≦y≦4.4, the complex oxide having an electrical resistivity of 1 Ωcm or less at 100° C. or higher.

5. An n-type thermoelectric material comprising the complex oxide of any one of Items 1 to 4.

6. A thermoelectric module comprising the n-type thermoelectric material of Item 5.

The complex oxide of the invention is a complex oxide whose composition is represented by the formula Ln₁₋ₓMₓNiO_{y} (hereinafter referred to as “complex oxide 1”), or a complex oxide whose composition is represented by the formula (Ln₁₋ₓMₓ)₂NiO_{y} (hereinafter referred to as “complex oxide 2”).

In complex oxides 1 and 2, Ln is a lanthanide and preferably is Ce, Pr, Nd, Sm, Eu, Gd, Tb, Dy, Ho, Er, Tm, or Lu. Among the above-mentioned lanthanides, Pr, Nd, Sm, Eu, Gd, Tb, Dy, Ho, Er, etc., are more preferable because such elements can easily provide a single-phase sample with no impurities.

In complex oxides 1 and 2, M is at least one element selected from the group consisting of Na, K, Li, Zn, Pb, Ba, Ca, Al, Bi, and rare earth elements being not the same as Ln. Specific examples of rare earth elements include Y, La, Ce, Pr, Nd, Sm, Eu, Gd, Tb, Dy, Ho, Er, Tm, Lu, etc. In particular, M is preferably at least one element selected from the group consisting of Na, K, Li, Zn, Pb, Ba, Ca, Al, Bi, Y, Ce, Pr, Nd, Sm, Eu, Gd, Tb, Dy, Ho, and Er because these elements can easily provide a single-phase sample with no impurities. M partially replaces the Ln sites, and is not the same rare earth element as Ln.

In complex oxide 1 represented by the formula Ln₁₋ₓMₓNiO_{y}, x is a value of not less than 0 and not more than 0.8 and y is a value of not less than 2.7 and not more than 3.3.

In complex oxide 2 represented by the formula (Ln₁₋ₓMₓ)₂NiO_{y}, x is a value of not less than 0 and not more than 0.8 and y is a value of not less than 3.6 and not more than 4.4.

Complex oxides 1 and 2 have a negative Seebeck coefficient and exhibit properties as n-type thermoelectric materials in that when a difference in temperature is created between both ends of the oxide material, the electric potential generated by the thermoelectromotive force is higher at the high-temperature side than at the low-temperature side. More specifically, complex oxides 1 and 2 have a negative Seebeck coefficient at 100° C. or higher.

Furthermore, complex oxides 1 and 2 have good electrical conductivity and low electrical resistivity, and more specifically, an electrical resistivity of 1 Ωcm or less at 100° C. or higher, in particular 100° C. to 700° C.

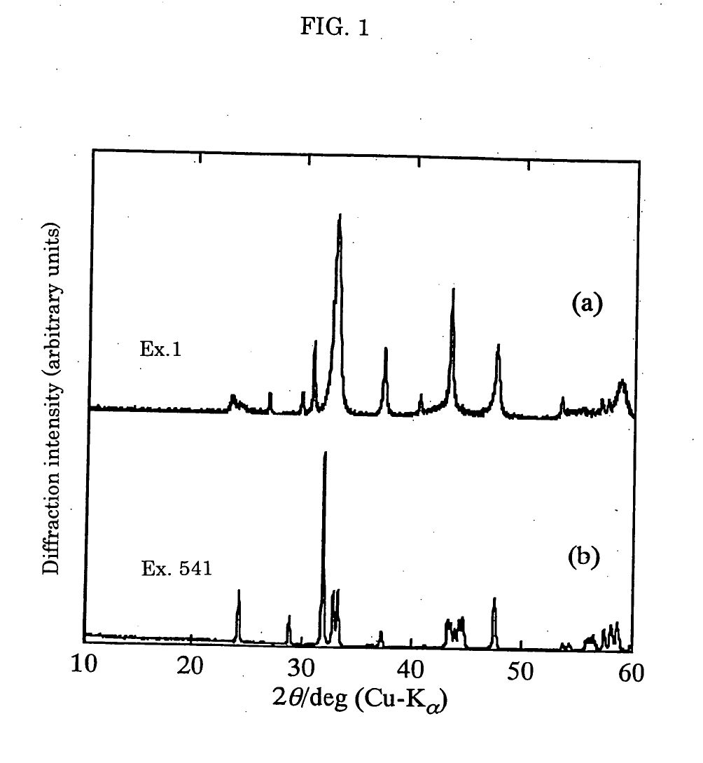

FIG. 1 shows an X-ray diffraction pattern of the complex oxide obtained in Example 1 given below, i.e., one embodiment of complex oxide 1. FIG. 1 also shows an X-ray diffraction pattern of the complex oxide obtained in Example 541 given below, i.e., one embodiment of complex oxide 2.

The X-ray diffraction patterns, although showing the presence of small amounts of impurities, clearly indicate that complex oxide 1 has a perovskite-type crystal structure and complex oxide 2 has a so-called layered perovskite-type structure, thus being a perovskite-related material.

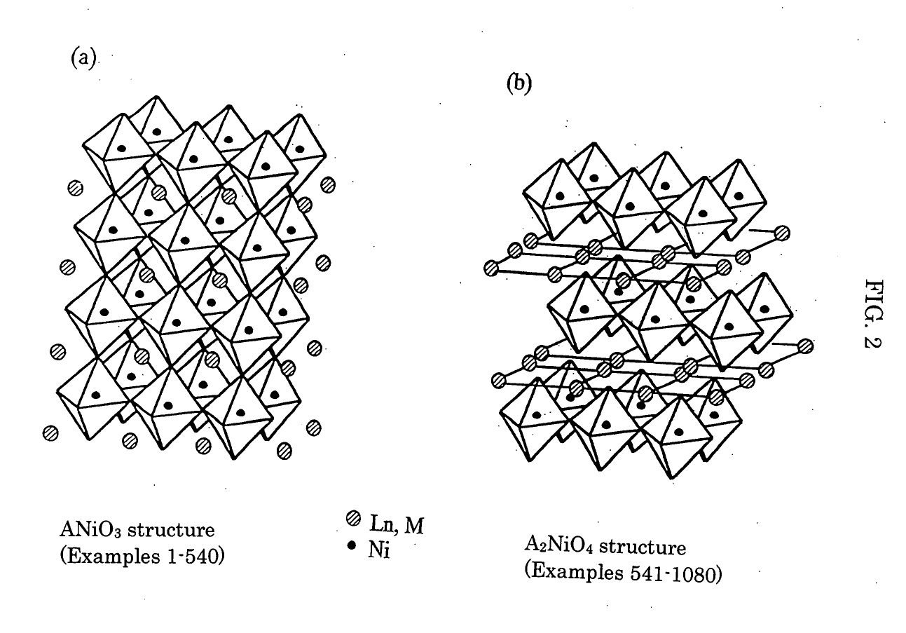

FIG. 2 schematically shows the crystal structures of complex oxides 1 and 2. As shown in FIG. 2, complex oxide 1 has a perovskite-type ANiO₃ structure and complex oxide 2 has a layered perovskite-type A₂NiO₄ structure in both of which the A sites are occupied by Ln which may be partially substituted by M.

Complex oxides 1 and 2 can be prepared by mixing the starting materials in such a proportion so as to have the same metal component ratio as the desired complex oxide, followed by sintering. More specifically, the starting materials are mixed to have the same Ln/M/Ni metal component ratio as in the formula Ln₁₋ₓMₓNiO_{y} or (Ln₁₋ₓMₓ)₂NiO_{y}, wherein Ln, M, x, and y are as defined above and the resulting mixture is sintered to provide the desired complex oxide.

The starting materials are not limited insofar as they can produce oxides when sintered. Examples of usable materials include metals, oxides, compounds (such as carbonates), and the like. Examples of usable sources of Nd include neodymium oxide (Nd₂O₃), neodymium carbonate (Nd₂(CO₃)₃), neodymium nitrate (Nd(NO₃)₃), neodymium chloride (NdCl₃), neodymium hydroxide (Nd(OH)₃), alkoxides, such as trimethoxy neodymium (Nd(OCH₃)₃), triethoxy neodymium (Nd(OC₂H₅)₃), tripropoxy neodymium (Nd(OC₃H₇)₃), etc.

Examples of usable sources of Ni are nickel oxide (NiO), nickel nitrate (Ni(NO₃)₂), nickel chloride (NiCl₂), nickel hydroxide (Ni(OH)₂), alkoxides such as dimethoxy nickel (Ni(OCH₃)₂), diethoxy nickel (Ni(OC₂H₅)₂) and dipropoxy nickel (Ni(OC₃H₇)₂), and the like. Similarly, examples of usable sources of other elements are oxides, chlorides, carbonates, nitrates, hydroxides, alkoxides and the like. Compounds containing two or more constituent elements of the complex oxide of the invention are also usable.

The sintering temperature and sintering time are not limited insofar as the desired complex oxide can be produced under such conditions. For example, the sintering may be performed at about 850° C. to about 1000° C. for about 20 to about 40 hours. When carbonates, organic compounds or the like are used as starting materials, the starting materials are preferably decomposed by calcination prior to sintering, and then sintered to give the desired complex oxide. For example, when carbonates are used as starting materials, they may be calcined at about 600° C. to about 800° C. for about 10 hours, and then sintered under the above-mentioned conditions.

Sintering means are not limited and any desired means such as electric furnaces and gas furnaces may be used. Usually, sintering may be conducted in an oxidizing atmosphere with a partial pressure of oxygen of about 1% or higher, such as in an oxygen stream or in air. When the starting materials contain a sufficient amount of oxygen, sintering in, for example, an inert atmosphere is also possible.

The amount of oxygen in a complex oxide to be produced can be controlled by adjusting the partial pressure of oxygen during sintering, sintering temperature, sintering time, etc. The higher the partial pressure of oxygen is, the higher the oxygen ratio in the above formulae can be.

The thus obtained complex oxides 1 and 2 of the invention have negative Seebeck coefficients and low electrical resistivities, i.e., an electrical resistivity of 1 Ωcm or less at 100° C. or higher, so that the oxides exhibit excellent thermoelectric conversion capabilities as n-type thermoelectric materials. Furthermore, the complex oxides have good heat resistance and chemical durability and are composed of elements of low toxicity and therefore highly practical as thermoelectric materials.

Complex oxides 1 and 2 of the invention with the above-mentioned properties can be effectively used as n-type thermoelectric materials in air at high temperatures.

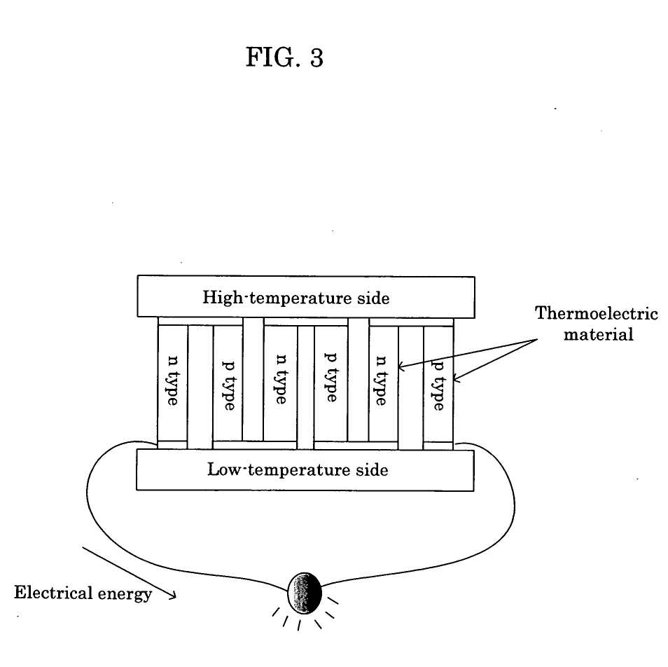

FIG. 3 is a view schematically showing a thermoelectric module produced using a thermoelectric material comprising a complex oxide of the invention as its n-type thermoelectric elements. The thermoelectric module has a structure similar to conventional thermoelectric modules and comprises a high-temperature side substrate, a low-temperature side substrate, p-type thermoelectric materials, n-type thermoelectric materials, electrodes, and conductive wires. In such a module, the complex oxide of the invention is used as an n-type thermoelectric material.

The complex oxides of the invention have negative Seebeck coefficients and low electrical resistivities and also have excellent heat resistance, chemical durability, etc.

The complex oxides of the invention with such properties can be effectively utilized as n-type thermoelectric materials in air at high temperatures, whereas such use is impossible with conventional intermetallic compounds. Accordingly, by incorporating the complex oxides of the invention as n-type thermoelectric elements into thermoelectric system, it becomes possible to effectively utilize thermal energy conventionally lost to the atmosphere.

### BEST MODE FOR CARRYING OUT THE INVENTION

Examples are given below to illustrate the invention in further detail.

### EXAMPLE 1

Using neodymium oxide (Nd₂O₃) as a source of Nd and nickel oxide (NiO) as a source of Ni, these starting materials were well mixed at a Nd:Ni ratio (element ratio) of 1.0:1.0. The mixture was molded by pressing, followed by sintering in an oxygen stream at 920° C. for 40 hours to prepare a complex oxide.

The complex oxide thus obtained had a composition represented by the formula NdNiO_{3.1}.

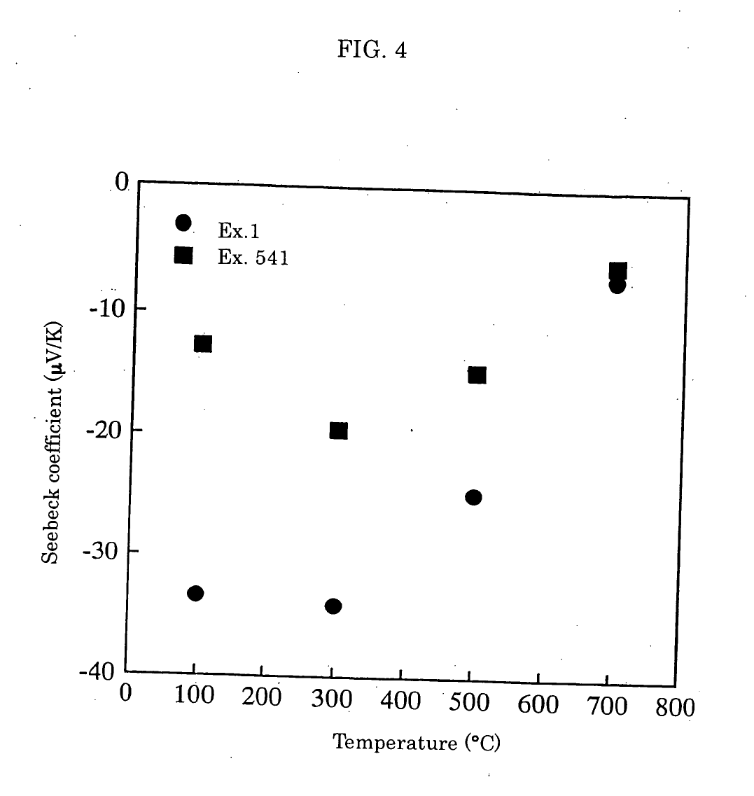

FIG. 4 is a graph showing the temperature dependency of the Seebeck coefficient (S) of the obtained complex oxide over the temperature range of 100° C. to 700° C. It is apparent from FIG. 4 that the complex oxide has a negative Seebeck coefficient at 100° C. or higher, thus being confirmed to be an n-type thermoelectric material in which the high-temperature side has a high electric potential.

In all the Examples described below, the Seebeck coefficient at 100° C. or higher was negative.

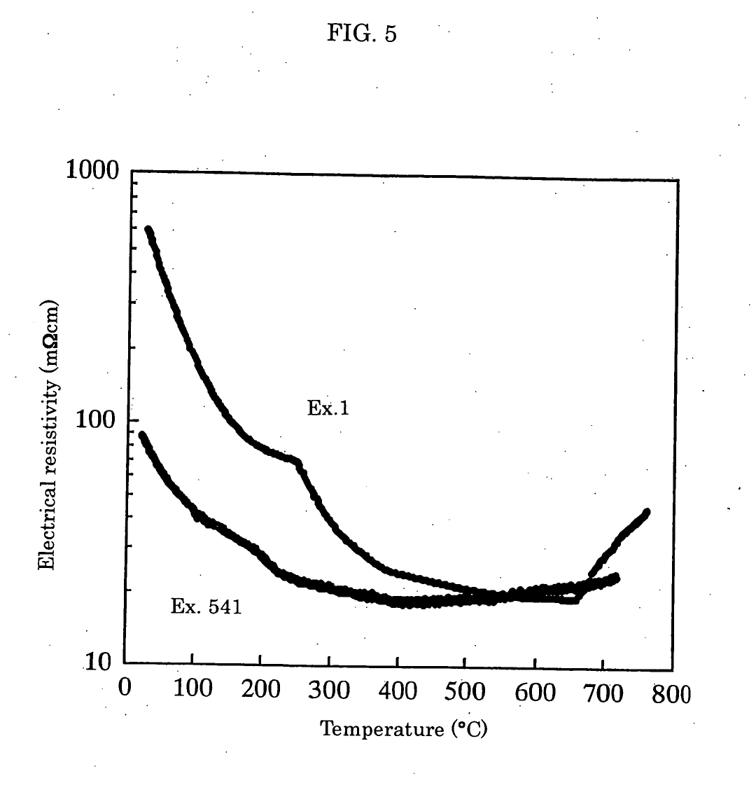

FIG. 5 is a graph showing the temperature dependency of the electrical resistivity of the complex oxide. FIG. 5 demonstrates that the complex oxide shows a low electrical resistivity, i.e., an electrical resistivity of about 1 Ωcm or less over the temperature range of 100° C. to 700° C.

In all the Examples described below, the electrical resistivity was 1 Ωcm or less over the temperature range of 100° C. to 700° C.

### EXAMPLES 2-1080

Starting materials were mixed at the element ratios shown in Tables 1 to 42, and the same procedure as in Example 1 was then conducted to provide complex oxides.

The sintering temperature was controlled within the range of 850° C. to 920° C. according to the desired complex oxide.

The complex oxides obtained in Examples 1 to 540 had a perovskite-type LnNiO₃ structure in which the Ln sites may be partially substituted by M, whereas those obtained in Examples 541 to 1080 had a layered perovskite-type Ln₂NiO₄ structure in which the Ln sites may be partially substituted by M.

Tables 1 to 42 below show the element ratios of the obtained complex oxides, their Seebeck coefficients at 700° C., and their electrical resistivities at 700° C.

With respect to the sintered complex oxide obtained in Example 541, the temperature dependency of the Seebeck coefficient (S) and the temperature dependency of the electrical resistivity over the temperature range of 100° C. to 700° C. are shown in FIG. 4 and FIG. 5, respectively.

TABLE 1
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 1 | Nd | — | 1:0:1:3.1 | −8 | 18 |
| 2 | Nd | Na | 0.99:0.01:1:2.9 | −15 | 30 |
| 3 | Nd | Na | 0.2:0.8:1:2.7 | −8 | 43 |
| 4 | Nd | K | 0.99:0.01:1:2.9 | −10 | 14 |
| 5 | Nd | K | 0.2:0.8:1:2.8 | −12 | 40 |
| 6 | Nd | Li | 0.99:0.01:1:3.0 | −21 | 30 |
| 7 | Nd | Li | 0.2:0.8:1:2.7 | −5 | 45 |
| 8 | Nd | Zn | 0.99:0.01:1:2.9 | −3 | 27 |
| 9 | Nd | Zn | 0.2:0.8:1:3.1 | −12 | 24 |
| 10 | Nd | Pb | 0.99:0.01:1:2.9 | −10 | 14 |
| 11 | Nd | Pb | 0.2:0.8:1:2.7 | −18 | 20 |
| 12 | Nd | Ba | 0.99:0.01:1:3.0 | −10 | 19 |
| 13 | Nd | Ba | 0.2:0.8:1:2.8 | −8 | 19 |
| 14 | Nd | Ca | 0.99:0.01:1:2.9 | −8 | 30 |
| 15 | Nd | Ca | 0.2:0.8:1:2.8 | −9 | 24 |
| 16 | Nd | Al | 0.99:0.01:1:3.3 | −7 | 22 |
| 17 | Nd | Al | 0.2:0.8:1:3.3 | −8 | 30 |
| 18 | Nd | Bi | 0.99:0.01:1:3.2 | −10 | 41 |
| 19 | Nd | Bi | 0.2:0.8:1:3.3 | −8 | 29 |
| 20 | Nd | Y | 0.99:0.01:1:2.9 | −5 | 34 |
| 21 | Nd | Y | 0.2:0.8:1:3.0 | −10 | 27 |
| 22 | Nd | La | 0.99:0.01:1:3.0 | −20 | 32 |
| 23 | Nd | La | 0.2:0.8:1:3.1 | −15 | 19 |
| 24 | Nd | Ce | 0.99:0.01:1:3.3 | −8 | 30 |
| 25 | Nd | Ce | 0.2:0.8:1:3.3 | −4 | 42 |
| 26 | Nd | Pr | 0.99:0.01:1:3.0 | −11 | 28 |
| 27 | Nd | Pr | 0.2:0.8:1:3.1 | −17 | 24 |
| 28 | Nd | Sm | 0.99:0.01:1:2.9 | −5 | 27 |
| 29 | Nd | Sm | 0.2:0.8:1:3.0 | −10 | 31 |
| 30 | Nd | Eu | 0.99:0.01:1:3.1 | −8 | 45 |

TABLE 2
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 31 | Nd | Eu | 0.2:0.8:1:3.2 | −6 | 36 |
| 32 | Nd | Gd | 0.99:0.01:1:2.9 | −7 | 24 |
| 33 | Nd | Gd | 0.2:0.8:1:3.0 | −8 | 35 |
| 34 | Nd | Tb | 0.99:0.01:1:2.8 | −10 | 30 |
| 35 | Nd | Tb | 0.2:0.8:1:3.0 | −10 | 45 |
| 36 | Nd | Dy | 0.99:0.01:1:2.9 | −9 | 33 |
| 37 | Nd | Dy | 0.2:0.8:1:3.1 | −10 | 24 |
| 38 | Nd | Ho | 0.99:0.01:1:3.1 | −11 | 19 |
| 39 | Nd | Ho | 0.2:0.8:1:3.3 | −12 | 31 |
| 40 | Nd | Er | 0.99:0.01:1:3.2 | −18 | 45 |
| 41 | Nd | Er | 0.2:0.8:1:3.3 | −20 | 33 |
| 42 | Nd | Tm | 0.99:0.01:1:3.0 | −15 | 30 |
| 43 | Nd | Tm | 0.2:0.8:1:3.0 | −5 | 19 |
| 44 | Nd | Lu | 0.99:0.01:1:3.1 | −6 | 27 |
| 45 | Nd | Lu | 0.2:0.8:1:3.2 | −5 | 31 |
| 46 | Ce | — | 1:0:1:3.1 | −10 | 45 |
| 47 | Ce | Na | 0.99:0.01:1:2.9 | −10 | 36 |
| 48 | Ce | Na | 0.2:0.8:1:2.7 | −15 | 24 |
| 49 | Ce | K | 0.99:0.01:1:2.8 | −12 | 35 |
| 50 | Ce | K | 0.2:0.8:1:2.8 | −20 | 30 |
| 51 | Ce | Li | 0.99:0.01:1:2.9 | −7 | 45 |
| 52 | Ce | Li | 0.2:0.8:1:2.7 | −8 | 33 |
| 53 | Ce | Zn | 0.99:0.01:1:3.1 | −5 | 24 |
| 54 | Ce | Zn | 0.2:0.8:1:3.3 | −12 | 19 |
| 55 | Ce | Pb | 0.99:0.01:1:2.9 | −10 | 31 |
| 56 | Ce | Pb | 0.2:0.8:1:2.8 | −18 | 45 |
| 57 | Ce | Ba | 0.99:0.01:1:2.9 | −12 | 33 |

TABLE 3
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 58 | Ce | Ba | 0.2:0.8:1:2.7 | −6 | 30 |
| 59 | Ce | Ca | 0.99:0.01:1:3.0 | −8 | 19 |
| 60 | Ce | Ca | 0.2:0.8:1:3.1 | −5 | 31 |
| 61 | Ce | Al | 0.99:0.01:1:3.3 | −10 | 45 |
| 62 | Ce | Al | 0.2:0.8:1:3.3 | −8 | 36 |
| 63 | Ce | Bi | 0.99:0.01:1:2.9 | −4 | 24 |
| 64 | Ce | Bi | 0.2:0.8:1:2.9 | −10 | 35 |
| 65 | Ce | Y | 0.99:0.01:1:2.9 | −12 | 30 |
| 66 | Ce | Y | 0.2:0.8:1:3.0 | −8 | 45 |
| 67 | Ce | La | 0.99:0.01:1:3.0 | −6 | 47 |
| 68 | Ce | La | 0.2:0.8:1:3.1 | −4 | 18 |
| 69 | Ce | Pr | 0.99:0.01:1:3.0 | −11 | 30 |
| 70 | Ce | Pr | 0.2:0.8:1:3.2 | −4 | 43 |
| 71 | Ce | Nd | 0.99:0.01:1:3.3 | −8 | 14 |
| 72 | Ce | Nd | 0.2:0.8:1:3.3 | −9 | 40 |
| 73 | Ce | Sm | 0.99:0.01:1:3.1 | −15 | 30 |
| 74 | Ce | Sm | 0.2:0.8:1:3.2 | −17 | 45 |
| 75 | Ce | Eu | 0.99:0.01:1:2.9 | −8 | 27 |
| 76 | Ce | Eu | 0.2:0.8:1:3.2 | −7 | 24 |
| 77 | Ce | Gd | 0.99:0.01:1:3.1 | −6 | 14 |
| 78 | Ce | Gd | 0.2:0.8:1:3.2 | −18 | 20 |
| 79 | Ce | Tb | 0.99:0.01:1:3.2 | −8 | 19 |
| 80 | Ce | Tb | 02:0.8:1:3.3 | −20 | 19 |
| 81 | Ce | Dy | 0.99:0.01:1:2.9 | −15 | 30 |
| 82 | Ce | Dy | 0.2:0.8:1:3.0 | −12 | 24 |
| 83 | Ce | Ho | 0.99:0.01:1:3.3 | −8 | 22 |

TABLE 4
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 84 | Ce | Ho | 0.2:0.8:1:3.2 | −5 | 30 |
| 85 | Ce | Er | 0.99:0.01:1:3.1 | −5 | 41 |
| 86 | Ce | Er | 0.2:0.8:1:3.2 | −8 | 29 |
| 87 | Ce | Tm | 0.99:0.01:1:2.9 | −7 | 34 |
| 88 | Ce | Tm | 0.2:0.8:1:3.3 | −11 | 27 |
| 89 | Ce | Lu | 0.99:0.01:1:3.1 | −13 | 49 |
| 90 | Ce | Lu | 0.2:0.8:1:3.2 | −15 | 29 |
| 91 | Pr | — | 1:0:1:3.1 | −10 | 34 |
| 92 | Pr | Na | 0.99:0.01:1:2.7 | −12 | 27 |
| 93 | Pr | Na | 0.2:0.8:1:2.9 | −6 | 32 |
| 94 | Pr | K | 0.99:0.01:1:3.0 | −8 | 19 |
| 95 | Pr | K | 0.2:0.8:1:2.9 | −10 | 30 |
| 96 | Pr | Li | 0.99:0.01:1:2.9 | −12 | 42 |
| 97 | Pr | Li | 0.2:0.8:1:2.7 | −20 | 28 |
| 98 | Pr | Zn | 0.99:0.01:1:3.1 | −22 | 24 |
| 99 | Pr | Zn | 0.2:0.8:1:3.3 | −12 | 27 |
| 100 | Pr | Pb | 0.99:0.01:1:2.9 | −8 | 31 |
| 101 | Pr | Pb | 0.2:0.8:1:2.7 | −18 | 45 |
| 102 | Pr | Ba | 0.99:0.01:1:3.0 | −12 | 36 |
| 103 | Pr | Ba | 0.2:0.8:1:2.7 | −5 | 24 |
| 104 | Pr | Ca | 0.99:0.01:1:2.9 | −8 | 35 |
| 105 | Pr | Ca | 0.2:0.8:1:2.7 | −6 | 30 |
| 106 | Pr | Al | 0.99:0.01:1:3.3 | −9 | 45 |
| 107 | Pr | Al | 0.2:0.8:1:3.3 | −12 | 33 |
| 108 | Pr | Bi | 0.99:0.01:1:3.3 | −5 | 24 |
| 109 | Pr | Bi | 0.2:0.8:1:3.3 | −21 | 19 |

TABLE 5
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 110 | Pr | Y | 0.99:0.01:1:3.0 | −20 | 31 |
| 111 | Pr | Y | 0.2:0.8:1:3.1 | −5 | 45 |
| 112 | Pr | La | 0.99:0.01:1:2.9 | −8 | 33 |
| 113 | Pr | La | 0.2:0.8:1:3.1 | −12 | 30 |
| 114 | Pr | Ce | 0.99:0.01:1:3.2 | −20 | 19 |
| 115 | Pr | Ce | 0.2:0.8:1:3.3 | −8 | 27 |
| 116 | Pr | Nd | 0.99:0.01:1:3.0 | −5 | 31 |
| 117 | Pr | Nd | 0.2:0.8:1:3.1 | −8 | 45 |
| 118 | Pr | Sm | 0.99:0.01:1:3.3 | −10 | 36 |
| 119 | Pr | Sm | 0.2:0.8:1:2.9 | −6 | 24 |
| 120 | Pr | Eu | 0.99:0.01:1:3.1 | −6 | 35 |
| 121 | Pr | Eu | 0.2:0.8:1:3.1 | −8 | 30 |
| 122 | Pr | Gd | 0.99:0.01:1:2.9 | −12 | 45 |
| 123 | Pr | Gd | 0.2:0.8:1:3.0 | −10 | 33 |
| 124 | Pr | Tb | 0.99:0.01:1:3.2 | −8 | 24 |
| 125 | Pr | Tb | 0.2:0.8:1:3.3 | −6 | 19 |
| 126 | Pr | Dy | 0.99:0.01:1:3.1 | −12 | 31 |
| 127 | Pr | Dy | 0.2:0.8:1:3.2 | −13 | 33 |
| 128 | Pr | Ho | 0.99:0.01:1:3.1 | −8 | 30 |
| 129 | Pr | Ho | 0.2:0.8:1:3.3 | −9 | 19 |
| 130 | Pr | Er | 0.99:0.01:1:2.9 | −20 | 31 |
| 131 | Pr | Er | 0.2:0.8:1:3.0 | −5 | 45 |
| 132 | Pr | Tm | 0.99:0.01:1:3.1 | −12 | 36 |
| 133 | Pr | Tm | 0.2:0.8:1:3.2 | −11 | 24 |
| 134 | Pr | Lu | 0.99:0.01:1:3.0 | −6 | 35 |
| 135 | Pr | Lu | 0.2:0.8:1:3.1 | −12 | 30 |
| 136 | Sm | — | 1:0:1:3.1 | −10 | 45 |

TABLE 6
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 137 | Sm | Na | 0.99:0.01:1:2.9 | −15 | 47 |
| 138 | Sm | Na | 0.2:0.8:1:2.7 | −8 | 18 |
| 139 | Sm | K | 0.99:0.01:1:2.9 | −10 | 30 |
| 140 | Sm | K | 0.2:0.8:1:2.8 | −12 | 43 |
| 141 | Sm | Li | 0.99:0.01:1:3.0 | −21 | 14 |
| 142 | Sm | Li | 0.2:0.8:1:2.7 | −5 | 40 |
| 143 | Sm | Zn | 0.99:0.01:1:2.9 | −3 | 30 |
| 144 | Sm | Zn | 0.2:0.8:1:3.1 | −12 | 45 |
| 145 | Sm | Pb | 0.99:0.01:1:2.9 | −10 | 27 |
| 146 | Sm | Pb | 0.2:0.8:1:2.7 | −18 | 24 |
| 147 | Sm | Ba | 0.99:0.01:1:3.0 | −10 | 14 |
| 148 | Sm | Ba | 0.2:0.8:1:2.8 | −8 | 20 |
| 149 | Sm | Ca | 0.99:0.01:1:2.9 | −8 | 19 |
| 150 | Sm | Ca | 0.2:0.8:1:2.8 | −9 | 19 |
| 151 | Sm | Al | 0.99:0.01:1:3.3 | −7 | 30 |
| 152 | Sm | Al | 0.2:0.8:1:3.3 | −8 | 24 |
| 153 | Sm | Bi | 0.99:0.01:1:3.2 | −10 | 22 |
| 154 | Sm | Bi | 0.2:0.8:1:3.3 | −8 | 30 |
| 155 | Sm | Y | 0.99:0.01:1:2.9 | −5 | 41 |
| 156 | Sm | Y | 0.2:0.8:1:3.0 | −10 | 29 |
| 157 | Sm | La | 0.99:0.01:1:3.0 | −20 | 34 |
| 158 | Sm | La | 0.2:0.8:1:3.1 | −15 | 27 |
| 159 | Sm | La | 0.99:0.01:1:3.3 | −8 | 49 |
| 160 | Sm | Ce | 0.2:0.8:1:3.3 | −4 | 33 |
| 161 | Sm | Pr | 0.99:0.01:1:3.0 | −11 | 30 |
| 162 | Sm | Pr | 0.2:0.8:1:3.1 | −17 | 19 |

TABLE 7
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 163 | Sm | Nd | 0.99:0.01:1:2.9 | −5 | 62 |
| 164 | Sm | Nd | 0.2:0.8:1:3.0 | −10 | 71 |
| 165 | Sm | Eu | 0.99:0.01:1:3.1 | −8 | 45 |
| 166 | Sm | Eu | 0.2:0.8:1:3.2 | −6 | 31 |
| 167 | Sm | Gd | 0.99:0.01:1:2.9 | −7 | 45 |
| 168 | Sm | Gd | 0.2:0.8:1:3.0 | −8 | 36 |
| 169 | Sm | Tb | 0.99:0.01:1:2.8 | −10 | 24 |
| 170 | Sm | Tb | 0.2:0.8:1:3.0 | −10 | 35 |
| 171 | Sm | Dy | 0.99:0.01:1:2.9 | −9 | 30 |
| 172 | Sm | Dy | 0.2:0.8:1:3.1 | −10 | 45 |
| 173 | Sm | Ho | 0.99:0.01:1:3.1 | −11 | 33 |
| 174 | Sm | Ho | 0.2:0.8:1:3.3 | −12 | 24 |
| 175 | Sm | Er | 0.99:0.01:1:3.2 | −18 | 19 |
| 176 | Sm | Er | 0.2:0.8:1:3.3 | −20 | 31 |
| 177 | Sm | Tm | 0.99:0.01:1:3.0 | −15 | 45 |
| 178 | Sm | Tm | 0.2:0.8:1:3.0 | −5 | 33 |
| 179 | Sm | Lu | 0.99:0.01:1:3.1 | −6 | 30 |
| 180 | Sm | Lu | 0.2:0.8:1:3.2 | −5 | 19 |
| 181 | Eu | — | 1:0:1:3.1 | −10 | 27 |
| 182 | Eu | Na | 0.99:0.01:1:2.7 | −12 | 31 |
| 183 | Eu | Na | 0.2:0.8:1:2.9 | −6 | 45 |
| 184 | Eu | K | 0.99:0.01:1:3.0 | −8 | 36 |
| 185 | Eu | K | 0.2:0.8:1:2.9 | −10 | 24 |
| 186 | Eu | Li | 0.99:0.01:1:2.9 | −12 | 35 |
| 187 | Eu | Li | 0.2:0.8:1:2.7 | −20 | 30 |
| 188 | Eu | Zn | 0.99:0.01:1:3.1 | −22 | 45 |
| 189 | Eu | Zn | 0.2:0.8:1:3.3 | −12 | 33 |

TABLE 8
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 190 | Eu | Pb | 0.99:0.01:1:2.9 | −8 | 24 |
| 191 | Eu | Pb | 0.2:0.8:1:2.7 | −18 | 19 |
| 192 | Eu | Ba | 0.99:0.01:1:3.0 | −12 | 31 |
| 193 | Eu | Ba | 0.2:0.8:1:2.7 | −5 | 45 |
| 194 | Eu | Ca | 0.99:0.01:1:2.9 | −8 | 33 |
| 195 | Eu | Ca | 0.2:0.8:1:2.7 | −6 | 30 |
| 196 | Eu | Al | 0.99:0.01:1:3.3 | −9 | 19 |
| 197 | Eu | Al | 0.2:0.8:1:3.3 | −12 | 31 |
| 198 | Eu | Bi | 0.99:0.01:1:3.3 | −5 | 30 |
| 199 | Eu | Bi | 0.2:0.8:1:3.3 | −21 | 45 |
| 200 | Eu | Y | 0.99:0.01:1:3.0 | −20 | 33 |
| 201 | Eu | Y | 0.2:0.8:1:3.1 | −5 | 24 |
| 202 | Eu | La | 0.99:0.01:1:2.9 | −8 | 19 |
| 203 | Eu | La | 0.2:0.8:1:3.1 | −12 | 31 |
| 204 | Eu | Ce | 0.99:0.01:1:3.2 | −20 | 33 |
| 205 | Eu | Ce | 0.2:0.8:1:3.3 | −8 | 30 |
| 206 | Eu | Pr | 0.99:0.01:1:3.0 | −5 | 19 |
| 207 | Eu | Pr | 0.2:0.8:1:3.1 | −8 | 31 |
| 208 | Eu | Nd | 0.99:0.01:1:3.3 | −10 | 45 |
| 209 | Eu | Nd | 0.2:0.8:1:2.9 | −6 | 36 |
| 210 | Eu | Sm | 0.99:0.01:1:3.1 | −6 | 24 |
| 211 | Eu | Sm | 0.2:0.8:1:3.1 | −8 | 35 |
| 212 | Eu | Gd | 0.99:0.01:1:2.9 | −12 | 30 |
| 213 | Eu | Gd | 0.2:0.8:1:3.0 | −10 | 45 |
| 214 | Eu | Tb | 0.99:0.01:1:3.2 | −8 | 47 |
| 215 | Eu | Tb | 0.2:0.8:1:3.3 | −6 | 18 |

TABLE 9
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 216 | Eu | Dy | 0.99:0.01:1:3.1 | −12 | 30 |
| 217 | Eu | Dy | 0.2:0.8:1:3.2 | −13 | 43 |
| 218 | Eu | Ho | 0.99:0.01:1:3.1 | −8 | 14 |
| 219 | Eu | Ho | 0.2:0.8:1:3.3 | −9 | 40 |
| 220 | Eu | Er | 0.99:0.01:1:2.9 | −20 | 30 |
| 221 | Eu | Er | 0.2:0.8:1:3.0 | −5 | 45 |
| 222 | Eu | Tm | 0.99:0.01:1:3.1 | −12 | 27 |
| 223 | Eu | Tm | 0.2:0.8:1:3.2 | −11 | 24 |
| 224 | Eu | Lu | 0.99:0.01:1:3.0 | −6 | 14 |
| 225 | Eu | Lu | 0.2:0.8:1:3.1 | −12 | 20 |
| 226 | Gd | — | 1:0:1:3.1 | −10 | 19 |
| 227 | Gd | Na | 0.99:0.01:1:2.9 | −10 | 19 |
| 228 | Gd | Na | 0.2:0.8:1:2.7 | −15 | 30 |
| 229 | Gd | K | 0.99:0.01:1:2.9 | −12 | 24 |
| 230 | Gd | K | 0.2:0.8:1:2.8 | −20 | 22 |
| 231 | Gd | Li | 0.99:0.01:1:3.0 | −7 | 30 |
| 232 | Gd | Li | 0.2:0.8:1:2.7 | −8 | 41 |
| 233 | Gd | Zn | 0.99:0.01:1:2.9 | −5 | 30 |
| 234 | Gd | Zn | 0.2:0.8:1:3.1 | −12 | 45 |
| 235 | Gd | Pb | 0.99:0.01:1:2.9 | −10 | 33 |
| 236 | Gd | Pb | 0.2:0.8:1:2.7 | −18 | 24 |
| 237 | Gd | Ba | 0.99:0.01:1:3.0 | −12 | 90 |
| 238 | Gd | Ba | 0.2:0.8:1:2.8 | −6 | 72 |
| 239 | Gd | Ca | 0.99:0.01:1:2.9 | −8 | 45 |
| 240 | Gd | Ca | 0.2:0.8:1:2.8 | −5 | 30 |
| 241 | Gd | Al | 0.99:0.01:1:3.3 | −10 | 41 |
| 242 | Gd | Al | 0.2:0.8:1:3.3 | −8 | 29 |

TABLE 10
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 243 | Gd | Bi | 0.99:0.01:1:3.2 | −4 | 34 |
| 244 | Gd | Bi | 0.2:0.8:1:3.3 | −10 | 27 |
| 245 | Gd | Y | 0.99:0.01:1:2.9 | −12 | 49 |
| 246 | Gd | Y | 0.2:0.8:1:3.0 | −8 | 33 |
| 247 | Gd | La | 0.99:0.01:1:3.0 | −6 | 30 |
| 248 | Gd | La | 0.2:0.8:1:3.1 | −4 | 19 |
| 249 | Gd | Ce | 0.99:0.01:1:3.3 | −11 | 36 |
| 250 | Gd | Ce | 0.2:0.8:1:3.3 | −4 | 24 |
| 251 | Gd | Pr | 0.99:0.01:1:3.0 | −8 | 35 |
| 252 | Gd | Pr | 0.2:0.8:1:3.1 | −9 | 31 |
| 253 | Gd | Nd | 0.99:0.01:1:2.9 | −15 | 45 |
| 254 | Gd | Nd | 0.2:0.8:1:3.0 | −17 | 36 |
| 255 | Gd | Sm | 0.99:0.01:1:3.1 | −8 | 24 |
| 256 | Gd | Sm | 0.2:0.8:1:3.2 | −7 | 35 |
| 257 | Gd | Eu | 0.99:0.01:1:2.9 | −6 | 30 |
| 258 | Gd | Eu | 0.2:0.8:1:3.0 | −18 | 45 |
| 259 | Gd | Tb | 0.99:0.01:1:2.8 | −8 | 33 |
| 260 | Gd | Tb | 0.2:0.8:1:3.0 | −20 | 24 |
| 261 | Gd | Dy | 0.99:0.01:1:2.9 | −15 | 19 |
| 262 | Gd | Dy | 0.2:0.8:1:3.1 | −12 | 31 |
| 263 | Gd | Ho | 0.99:0.01:1:3.1 | −8 | 45 |
| 264 | Gd | Ho | 0.2:0.8:1:3.3 | −5 | 33 |
| 265 | Gd | Er | 0.99:0.01:1:3.2 | −5 | 30 |
| 266 | Gd | Er | 0.2:0.8:1:3.3 | −8 | 19 |
| 267 | Gd | Tm | 0.99:0.01:1:3.0 | −7 | 27 |
| 268 | Gd | Tm | 0.2:0.8:1:3.0 | −11 | 31 |

TABLE 11
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 269 | Gd | Lu | 0.99:0.01:1:3.1 | −13 | 45 |
| 270 | Gd | Lu | 0.2:0.8:1:3.2 | −15 | 36 |
| 271 | Tb | — | 1:0:1:3.1 | −10 | 24 |
| 272 | Tb | Na | 0.99:0.01:1:2.9 | −10 | 35 |
| 273 | Tb | Na | 0.2:0.8:1:2.7 | −15 | 30 |
| 274 | Tb | K | 0.99:0.01:1:2.8 | −12 | 45 |
| 275 | Tb | K | 0.2:0.8:1:2.8 | −20 | 33 |
| 276 | Tb | Li | 0.99:0.01:1:2.9 | −7 | 24 |
| 277 | Tb | Li | 0.2:0.8:1:2.7 | −8 | 19 |
| 278 | Tb | Zn | 0.99:0.01:1:3.1 | −5 | 31 |
| 279 | Tb | Zn | 0.2:0.8:1:3.3 | −12 | 45 |
| 280 | Tb | Pb | 0.99:0.01:1:2.9 | −10 | 33 |
| 281 | Tb | Pb | 0.2:0.8:1:2.8 | −18 | 30 |
| 282 | Tb | Ba | 0.99:0.01:1:2.9 | −12 | 19 |
| 283 | Tb | Ba | 0.2:0.8:1:2.7 | −6 | 31 |
| 284 | Tb | Ca | 0.99:0.01:1:3.0 | −8 | 30 |
| 285 | Tb | Ca | 0.2:0.8:1:3.1 | −5 | 45 |
| 286 | Tb | Al | 0.99:0.01:1:3.3 | −10 | 33 |
| 287 | Tb | Al | 0.2:0.8:1:3.3 | −8 | 24 |
| 288 | Tb | Bi | 0.99:0.01:1:2.9 | −4 | 19 |
| 289 | Tb | Bi | 0.2:0.8:1:2.9 | −10 | 31 |
| 290 | Tb | Y | 0.99:0.01:1:2.9 | −12 | 50 |
| 291 | Tb | Y | 0.2:0.8:1:3.0 | −8 | 33 |
| 292 | Tb | La | 0.99:0.01:1:3.0 | −6 | 49 |
| 293 | Tb | La | 0.2:0.8:1:3.1 | −4 | 14 |
| 294 | Tb | Ce | 0.99:0.01:1:3.0 | −11 | 20 |

TABLE 12
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 295 | Tb | Ce | 0.2:0.8:1:3.2 | −4 | 19 |
| 296 | Tb | Pr | 0.99:0.01:1:3.3 | −8 | 19 |
| 297 | Tb | Pr | 0.2:0.8:1:3.3 | −9 | 30 |
| 298 | Tb | Nd | 0.99:0.01:1:3.1 | −15 | 24 |
| 299 | Tb | Nd | 0.2:0.8:1:3.2 | −17 | 22 |
| 300 | Tb | Sm | 0.99:0.01:1:2.9 | −8 | 30 |
| 301 | Tb | Sm | 0.2:0.8:1:3.2 | −7 | 41 |
| 302 | Tb | Eu | 0.99:0.01:1:3.1 | −6 | 29 |
| 303 | Tb | Eu | 0.2:0.8:1:3.2 | −18 | 34 |
| 304 | Tb | Gd | 0.99:0.01:1:3.2 | −8 | 27 |
| 305 | Tb | Gd | 0.2:0.8:1:3.3 | −20 | 49 |
| 306 | Tb | Dy | 0.99:0.01:1:2.9 | −15 | 29 |
| 307 | Tb | Dy | 0.2:0.8:1:3.0 | −12 | 34 |
| 308 | Tb | Ho | 0.99:0.01:1:3.3 | −8 | 27 |
| 309 | Tb | Ho | 0.2:0.8:1:3.2 | −5 | 32 |
| 310 | Tb | Er | 0.99:0.01:1:3.1 | −5 | 19 |
| 311 | Tb | Er | 0.2:0.8:1:3.2 | −8 | 30 |
| 312 | Tb | Tm | 0.99:0.01:1:2.9 | −7 | 42 |
| 313 | Tb | Tm | 0.2:0.8:1:3.3 | −11 | 28 |
| 314 | Tb | Lu | 0.99:0.01:1:3.1 | −13 | 24 |
| 315 | Tb | Lu | 0.2:0.8:1:3.2 | −15 | 27 |
| 316 | Dy | — | 1:0:1:3.1 | −10 | 31 |
| 317 | Dy | Na | 0.99:0.01:1:2.7 | −15 | 45 |
| 318 | Dy | Na | 0.2:0.8:1:2.9 | −8 | 36 |
| 319 | Dy | K | 0.99:0.01:1:3.0 | −10 | 24 |
| 320 | Dy | K | 0.2:0.8:1:2.9 | −12 | 35 |

TABLE 13
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 321 | Dy | Li | 0.99:0.01:1:2.9 | −21 | 30 |
| 322 | Dy | Li | 0.2:0.8:1:2.7 | −5 | 45 |
| 323 | Dy | Zn | 0.99:0.01:1:3.1 | −3 | 33 |
| 324 | Dy | Zn | 0.2:0.8:1:3.3 | −12 | 24 |
| 325 | Dy | Pb | 0.99:0.01:1:2.9 | −10 | 19 |
| 326 | Dy | Pb | 0.2:0.8:1:2.7 | −18 | 31 |
| 327 | Dy | Ba | 0.99:0.01:1:3.0 | −10 | 45 |
| 328 | Dy | Ba | 0.2:0.8:1:2.7 | −8 | 33 |
| 329 | Dy | Ca | 0.99:0.01:1:2.9 | −8 | 30 |
| 330 | Dy | Ca | 0.2:0.8:1:2.7 | −9 | 19 |
| 331 | Dy | Al | 0.99:0.01:1:3.3 | −7 | 27 |
| 332 | Dy | Al | 0.2:0.8:1:3.3 | −8 | 14 |
| 333 | Dy | Bi | 0.99:0.01:1:3.3 | −10 | 20 |
| 334 | Dy | Bi | 0.2:0.8:1:3.3 | −8 | 19 |
| 335 | Dy | Y | 0.99:0.01:1:3.0 | −5 | 19 |
| 336 | Dy | Y | 0.2:0.8:1:3.1 | −10 | 30 |
| 337 | Dy | La | 0.99:0.01:1:2.9 | −20 | 24 |
| 338 | Dy | La | 0.2:0.8:1:3.1 | −15 | 22 |
| 339 | Dy | Ce | 0.99:0.01:1:3.2 | −8 | 30 |
| 340 | Dy | Ce | 0.2:0.8:1:3.3 | −4 | 41 |
| 341 | Dy | Pr | 0.99:0.01:1:3.0 | −11 | 29 |
| 342 | Dy | Pr | 0.2:0.8:1:3.1 | −17 | 34 |
| 343 | Dy | Nd | 0.99:0.01:1:3.3 | −5 | 27 |
| 344 | Dy | Nd | 0.2:0.8:1:2.9 | −10 | 49 |
| 345 | Dy | Sm | 0.99:0.01:1:3.1 | −8 | 29 |
| 346 | Dy | Sm | 0.2:0.8:1:3.1 | −6 | 34 |

TABLE 14
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 347 | Dy | Eu | 0.99:0.01:1:2.9 | −7 | 27 |
| 348 | Dy | Eu | 0.2:0.8:1:3.0 | −8 | 32 |
| 349 | Dy | Gd | 0.99:0.01:1:3.2 | −10 | 19 |
| 350 | Dy | Gd | 0.2:0.8:1:3.3 | −10 | 49 |
| 351 | Dy | Tb | 0.99:0.01:1:3.1 | −9 | 45 |
| 352 | Dy | Tb | 0.2:0.8:1:3.2 | −10 | 33 |
| 353 | Dy | Ho | 0.99:0.01:1:3.1 | −11 | 24 |
| 354 | Dy | Ho | 0.2:0.8:1:3.3 | −12 | 19 |
| 355 | Dy | Er | 0.99:0.01:1:2.9 | −18 | 31 |
| 356 | Dy | Er | 0.2:0.8:1:3.0 | −20 | 45 |
| 357 | Dy | Tm | 0.99:0.01:1:3.1 | −15 | 33 |
| 358 | Dy | Tm | 0.2:0.8:1:3.2 | −5 | 30 |
| 359 | Dy | Lu | 0.99:0.01:1:3.0 | −6 | 19 |
| 360 | Dy | Lu | 0.2:0.8:1:3.1 | −5 | 27 |
| 361 | Ho | — | 1:0:1:3.1 | −10 | 31 |
| 362 | Ho | Na | 0.99:0.01:1:2.7 | −12 | 45 |
| 363 | Ho | Na | 0.2:0.8:1:2.9 | −6 | 36 |
| 364 | Ho | K | 0.99:0.01:1:3.0 | −8 | 24 |
| 365 | Ho | K | 0.2:0.8:1:2.9 | −10 | 35 |
| 366 | Ho | Li | 0.99:0.01:1:2.9 | −12 | 30 |
| 367 | Ho | Li | 0.2:0.8:1:2.7 | −20 | 45 |
| 368 | Ho | Zn | 0.99:0.01:1:3.1 | −22 | 33 |
| 369 | Ho | Zn | 0.2:0.8:1:3.3 | −12 | 24 |
| 370 | Ho | Pb | 0.99:0.01:1:2.9 | −8 | 19 |
| 371 | Ho | Pb | 0.2:0.8:1:2.7 | −18 | 31 |
| 372 | Ho | Ba | 0.99:0.01:1:3.0 | −12 | 45 |

TABLE 15
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 373 | Ho | Ba | 0.2:0.8:1:2.7 | −5 | 33 |
| 374 | Ho | Ca | 0.99:0.01:1:2.9 | −8 | 30 |
| 375 | Ho | Ca | 0.2:0.8:1:2.7 | −6 | 19 |
| 376 | Ho | Al | 0.99:0.01:1:3.3 | −9 | 32 |
| 377 | Ho | Al | 0.2:0.8:1:3.3 | −12 | 50 |
| 378 | Ho | Bi | 0.99:0.01:1:3.3 | −5 | 15 |
| 379 | Ho | Bi | 0.2:0.8:1:3.3 | −21 | 27 |
| 380 | Ho | Y | 0.99:0.01:1:3.0 | −20 | 49 |
| 381 | Ho | Y | 0.2:0.8:1:3.1 | −5 | 29 |
| 382 | Ho | La | 0.99:0.01:1:2.9 | −8 | 58 |
| 383 | Ho | La | 0.2:0.8:1:3.1 | −12 | 35 |
| 384 | Ho | Ce | 0.99:0.01:1:3.2 | −20 | 40 |
| 385 | Ho | Ce | 0.2:0.8:1:3.3 | −8 | 27 |
| 386 | Ho | Pr | 0.99:0.01:1:3.0 | −5 | 49 |
| 387 | Ho | Pr | 0.2:0.8:1:3.1 | −8 | 29 |
| 388 | Ho | Nd | 0.99:0.01:1:3.3 | −10 | 39 |
| 389 | Ho | Nd | 0.2:0.8:1:2.9 | −6 | 14 |
| 390 | Ho | Sm | 0.99:0.01:1:3.1 | −6 | 20 |
| 391 | Ho | Sm | 0.2:0.8:1:3.1 | −8 | 19 |
| 392 | Ho | Eu | 0.99:0.01:1:2.9 | −12 | 19 |
| 393 | Ho | Eu | 0.2:0.8:1:3.0 | −10 | 30 |
| 394 | Ho | Gd | 0.99:0.01:1:3.2 | −8 | 24 |
| 395 | Ho | Gd | 0.2:0.8:1:3.3 | −6 | 22 |
| 396 | Ho | Tb | 0.99:0.01:1:3.1 | −12 | 30 |
| 397 | Ho | Tb | 0.2:0.8:1:3.2 | −13 | 41 |
| 398 | Ho | Dy | 0.99:0.01:1:3.1 | −8 | 29 |

TABLE 16
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 399 | Ho | Dy | 0.2:0.8:1:3.3 | −9 | 34 |
| 400 | Ho | Er | 0.99:0.01:1:2.9 | −20 | 27 |
| 401 | Ho | Er | 0.2:0.8:1:3.0 | −5 | 49 |
| 402 | Ho | Tm | 0.99:0.01:1:3.1 | −12 | 29 |
| 403 | Ho | Tm | 0.2:0.8:1:3.2 | −11 | 34 |
| 404 | Ho | Lu | 0.99:0.01:1:3.0 | −6 | 27 |
| 405 | Ho | Lu | 0.2:0.8:1:3.1 | −12 | 32 |
| 406 | Er | — | 1:0:1:3.1 | −10 | 19 |
| 407 | Er | Na | 0.99:0.01:1:2.9 | −15 | 30 |
| 408 | Er | Na | 0.2:0.8:1:2.7 | −8 | 42 |
| 409 | Er | K | 0.99:0.01:1:2.9 | −10 | 28 |
| 410 | Er | K | 0.2:0.8:1:2.8 | −12 | 24 |
| 411 | Er | Li | 0.99:0.01:1:3.0 | −21 | 27 |
| 412 | Er | Li | 0.2:0.8:1:2.7 | −5 | 31 |
| 413 | Er | Zn | 0.99:0.01:1:2.9 | −3 | 45 |
| 414 | Er | Zn | 0.2:0.8:1:3.1 | −12 | 36 |
| 415 | Er | Pb | 0.99:0.01:1:2.9 | −10 | 24 |
| 416 | Er | Pb | 0.2:0.8:1:2.7 | −18 | 35 |
| 417 | Er | Ba | 0.99:0.01:1:3.0 | −10 | 30 |
| 418 | Er | Ba | 0.2:0.8:1:2.8 | −8 | 45 |
| 419 | Er | Ca | 0.99:0.01:1:2.9 | −8 | 33 |
| 420 | Er | Ca | 0.2:0.8:1:2.8 | −9 | 24 |
| 421 | Er | Al | 0.99:0.01:1:3.3 | −7 | 19 |
| 422 | Er | Al | 0.2:0.8:1:3.3 | −8 | 31 |
| 423 | Er | Bi | 0.99:0.01:1:3.2 | −10 | 45 |
| 424 | Er | Bi | 0.2:0.8:1:3.3 | −8 | 30 |

TABLE 17
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 425 | Er | Y | 0.99:0.01:1:2.9 | −5 | 19 |
| 426 | Er | Y | 0.2:0.8:1:3.0 | −10 | 27 |
| 427 | Er | La | 0.99:0.01:1:3.0 | −20 | 31 |
| 428 | Er | La | 0.2:0.8:1:3.1 | −15 | 45 |
| 429 | Er | Ce | 0.99:0.01:1:3.3 | −8 | 36 |
| 430 | Er | Ce | 0.2:0.8:1:3.3 | −4 | 24 |
| 431 | Er | Pr | 0.99:0.01:1:3.0 | −11 | 35 |
| 432 | Er | Pr | 0.2:0.8:1:3.1 | −17 | 30 |
| 433 | Er | Nd | 0.99:0.01:1:2.9 | −5 | 45 |
| 434 | Er | Nd | 0.2:0.8:1:3.0 | −10 | 33 |
| 435 | Er | Sm | 0.99:0.01:1:3.1 | −8 | 24 |
| 436 | Er | Sm | 0.2:0.8:1:3.2 | −6 | 19 |
| 437 | Er | Eu | 0.99:0.01:1:2.9 | −7 | 31 |
| 438 | Er | Eu | 0.2:0.8:1:3.0 | −8 | 45 |
| 439 | Er | Gd | 0.99:0.01:1:2.8 | −10 | 33 |
| 440 | Er | Gd | 0.2:0.8:1:3.0 | −10 | 30 |
| 441 | Er | Tb | 0.99:0.01:1:2.9 | −9 | 19 |
| 442 | Er | Tb | 0.2:0.8:1:3.1 | −10 | 27 |
| 443 | Er | Dy | 0.99:0.01:1:3.1 | −11 | 49 |
| 444 | Er | Dy | 0.2:0.8:1:3.3 | −12 | 29 |
| 445 | Er | Ho | 0.99:0.01:1:3.2 | −18 | 34 |
| 446 | Er | Ho | 0.2:0.8:1:3.3 | −20 | 27 |
| 447 | Er | Tm | 0.99:0.01:1:3.0 | −15 | 32 |
| 448 | Er | Tm | 0.2:0.8:1:3.0 | −5 | 19 |
| 449 | Er | Lu | 0.99:0.01:1:3.1 | −6 | 49 |
| 450 | Er | Lu | 0.2:0.8:1:3.2 | −5 | 45 |

TABLE 18
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 451 | Tm | — | 1:0:1:3.1 | −10 | 33 |
| 452 | Tm | Na | 0.99:0.01:1:2.9 | −10 | 24 |
| 453 | Tm | Na | 0.2:0.8:1:2.7 | −15 | 19 |
| 454 | Tm | K | 0.99:0.01:1:2.8 | −12 | 31 |
| 455 | Tm | K | 0.2:0.8:1:2.8 | −20 | 45 |
| 456 | Tm | Li | 0.99:0.01:1:2.9 | −7 | 75 |
| 457 | Tm | Li | 0.2:0.8:1:2.7 | −8 | 55 |
| 458 | Tm | Zn | 0.99:0.01:1:3.1 | −5 | 19 |
| 459 | Tm | Zn | 0.2:0.8:1:3.3 | −12 | 31 |
| 460 | Tm | Pb | 0.99:0.01:1:2.9 | −10 | 45 |
| 461 | Tm | Pb | 0.2:0.8:1:2.8 | −18 | 30 |
| 462 | Tm | Ba | 0.99:0.01:1:2.9 | −12 | 19 |
| 463 | Tm | Ba | 0.2:0.8:1:2.7 | −6 | 27 |
| 464 | Tm | Ca | 0.99:0.01:1:3.0 | −8 | 31 |
| 465 | Tm | Ca | 0.2:0.8:1:3.1 | −5 | 45 |
| 466 | Tm | Al | 0.99:0.01:1:3.3 | −10 | 36 |
| 467 | Tm | Al | 0.2:0.8:1:3.3 | −8 | 24 |
| 468 | Tm | Bi | 0.99:0.01:1:2.9 | −4 | 35 |
| 469 | Tm | Bi | 0.2:0.8:1:2.9 | −10 | 30 |
| 470 | Tm | Y | 0.99:0.01:1:2.9 | −12 | 45 |
| 471 | Tm | Y | 0.2:0.8:1:3.0 | −8 | 33 |
| 472 | Tm | La | 0.99:0.01:1:3.0 | −6 | 58 |
| 473 | Tm | La | 0.2:0.8:1:3.1 | −4 | 35 |
| 474 | Tm | Ce | 0.99:0.01:1:3.0 | −11 | 40 |
| 475 | Tm | Ce | 0.2:0.8:1:3.2 | −4 | 30 |
| 476 | Tm | Pr | 0.99:0.01:1:3.3 | −8 | 19 |

TABLE 19
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mO cm) |
| 477 | Tm | Pr | 0.2:0.8:1:3.3 | −9 | 27 |
| 478 | Tm | Nd | 0.99:0.01:1:3.1 | −15 | 31 |
| 479 | Tm | Nd | 0.2:0.8:1:3.2 | −17 | 45 |
| 480 | Tm | Sm | 0.99:0.01:1:2.9 | −8 | 36 |
| 481 | Tm | Sm | 0.2:0.8:1:3.2 | −7 | 24 |
| 482 | Tm | Eu | 0.99:0.01:1:3.1 | −6 | 35 |
| 483 | Tm | Eu | 0.2:0.8:1:3.2 | −18 | 30 |
| 484 | Tm | Gd | 0.99:0.01:1:3.2 | −8 | 45 |
| 485 | Tm | Gd | 0.2:0.8:1:3.3 | −20 | 33 |
| 486 | Tm | Tb | 0.99:0.01:1:2.9 | −15 | 24 |
| 487 | Tm | Tb | 0.2:0.8:1:3.0 | −12 | 19 |
| 488 | Tm | Dy | 0.99:0.01:1:3.3 | −8 | 31 |
| 489 | Tm | Dy | 0.2:0.8:1:3.2 | −5 | 45 |
| 490 | Tm | Ho | 0.99:0.01:1:3.1 | −5 | 33 |
| 491 | Tm | Ho | 0.2:0.8:1:3.2 | −8 | 30 |
| 492 | Tm | Er | 0.99:0.01:1:2.9 | −7 | 19 |
| 493 | Tm | Er | 0.2:0.8:1:3.3 | −11 | 27 |
| 494 | Tm | Lu | 0.99:0.01:1:3.1 | −13 | 35 |
| 495 | Tm | Lu | 0.2:0.8:1:3.2 | −15 | 40 |
| 496 | Lu | — | 1:0:1:3.1 | −10 | 30 |
| 497 | Lu | Na | 0.99:0.01:1:2.7 | −12 | 19 |
| 498 | Lu | Na | 0.2:0.8:1:2.9 | −6 | 27 |
| 499 | Lu | K | 0.99:0.01:1:3.0 | −8 | 31 |
| 500 | Lu | K | 0.2:0.8:1:2.9 | −10 | 45 |
| 501 | Lu | Li | 0.99:0.01:1:2.9 | −12 | 35 |
| 502 | Lu | Li | 0.2:0.8:1:2.7 | −20 | 40 |

TABLE 20
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 503 | Lu | Zn | 0.99:0.01:1:3.1 | −22 | 30 |
| 504 | Lu | Zn | 0.2:0.8:1:3.3 | −12 | 19 |
| 505 | Lu | Pb | 0.99:0.01:1:2.9 | −8 | 27 |
| 506 | Lu | Pb | 0.2:0.8:1:2.7 | −18 | 31 |
| 507 | Lu | Ba | 0.99:0.01:1:3.0 | −12 | 45 |
| 508 | Lu | Ba | 0.2:0.8:1:2.7 | −5 | 36 |
| 509 | Lu | Ca | 0.99:0.01:1:2.9 | −8 | 24 |
| 510 | Lu | Ca | 0.2:0.8:1:2.7 | −6 | 35 |
| 511 | Lu | Al | 0.99:0.01:1:3.3 | −9 | 30 |
| 512 | Lu | Al | 0.2:0.8:1:3.3 | −12 | 45 |
| 513 | Lu | Bi | 0.99:0.01:1:3.3 | −5 | 33 |
| 514 | Lu | Bi | 0.2:0.8:1:3.3 | −21 | 35 |
| 515 | Lu | Y | 0.99:0.01:1:3.0 | −20 | 40 |
| 516 | Lu | Y | 0.2:0.8:1:3.1 | −5 | 30 |
| 517 | Lu | La | 0.99:0.01:1:2.9 | −8 | 19 |
| 518 | Lu | La | 0.2:0.8:1:3.1 | −12 | 27 |
| 519 | Lu | Ce | 0.99:0.01:1:3.2 | −20 | 31 |
| 520 | Lu | Ce | 0.2:0.8:1:3.3 | −8 | 45 |
| 521 | Lu | Pr | 0.99:0.01:1:3.0 | −5 | 36 |
| 522 | Lu | Pr | 0.2:0.8:1:3.1 | −8 | 24 |
| 523 | Lu | Nd | 0.99:0.01:1:3.3 | −10 | 35 |
| 524 | Lu | Nd | 0.2:0.8:1:2.9 | −6 | 30 |
| 525 | Lu | Sm | 0.99:0.01:1:3.1 | −6 | 45 |
| 526 | Lu | Sm | 0.2:0.8:1:3.1 | −8 | 33 |
| 527 | Lu | Eu | 0.99:0.01:1:2.9 | −12 | 35 |
| 528 | Lu | Eu | 0.2:0.8:1:3.0 | −10 | 40 |

TABLE 21
Ln₁₋ₓMₓNiO_{y}

| | | | | Seebeck | Electrical |
|---|---|---|---|---|---|
| | | | | coefficient | resistivity |
| | | | | at 700° C. | at 700° C. |
| No. | Ln | M | Ln:M:Ni:O | (μVK⁻¹) | (mΩcm) |
| 529 | Lu | Gd | 0.99:0.01:1:3.2 | −8 | 30 |
| 530 | Lu | Gd | 0.2:0.8:1:3.3 | −6 | 49 |
| 531 | Lu | Tb | 0.99:0.01:1:3.1 | −12 | 31 |
| 532 | Lu | Tb | 0.2:0.8:1:3.2 | −13 | 45 |
| 533 | Lu | Dy | 0.99:0.01:1:3.1 | −8 | 75 |
| 534 | Lu | Dy | 0.2:0.8:1:3.3 | −9 | 55 |
| 535 | Lu | Ho | 0.99:0.01:1:2.9 | −20 | 19 |
| 536 | Lu | Ho | 0.2:0.8:1:3.0 | −5 | 31 |
| 537 | Lu | Er | 0.99:0.01:1:3.1 | −12 | 45 |
| 538 | Lu | Er | 0.2:0.8:1:3.2 | −11 | 30 |
| 539 | Lu | Tm | 0.99:0.01:1:3.0 | −6 | 19 |
| 540 | Lu | Tm | 0.2:0.8:1:3.1 | −12 | 27 |

TABLE 22
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 541 | Nd | — | 1:0:1:4.0 | −6 | 25 |
| 542 | Nd | Na | 0.99:0.01:1:3.6 | −12 | 25 |
| 543 | Nd | Na | 0.2:0.8:1:3.9 | −20 | 38 |
| 544 | Nd | K | 0.99:0.01:1:3.7 | −22 | 34 |
| 545 | Nd | K | 0.2:0.8:1:3.8 | −12 | 24 |
| 546 | Nd | Li | 0.99:0.01:1:3.8 | −8 | 17 |
| 547 | Nd | Li | 0.2:0.8:1:3.6 | −18 | 35 |
| 548 | Nd | Zn | 0.99:0.01:1:4.0 | −12 | 38 |
| 549 | Nd | Zn | 0.2:0.8:1:3.8 | −5 | 44 |
| 550 | Nd | Pb | 0.99:0.01:1:3.6 | −8 | 36 |
| 551 | Nd | Pb | 0.2:0.8:1:3.6 | −6 | 30 |
| 552 | Nd | Ba | 0.99:0.01:1:3.9 | −9 | 42 |
| 553 | Nd | Ba | 0.2:0.8:1:4.0 | −12 | 28 |
| 554 | Nd | Ca | 0.99:0.01:1:3.8 | −5 | 24 |
| 555 | Nd | Ca | 0.2:0.8:1:4.0 | −21 | 27 |
| 556 | Nd | Al | 0.99:0.01:1:4.0 | −20 | 31 |
| 557 | Nd | Al | 0.2:0.8:1:4.1 | −5 | 45 |
| 558 | Nd | Bi | 0.99:0.01:1:4.2 | −15 | 36 |
| 559 | Nd | Bi | 0.2:0.8:1:4.4 | −8 | 24 |
| 560 | Nd | Y | 0.99:0.01:1:4.2 | −12 | 35 |
| 561 | Nd | Y | 0.2:0.8:1:4.3 | −10 | 30 |
| 562 | Nd | La | 0.99:0.01:1:4.0 | −19 | 45 |
| 563 | Nd | La | 0.2:0.8:1:4.1 | −8 | 33 |
| 564 | Nd | Ce | 0.99:0.01:1:4.2 | −5 | 24 |
| 565 | Nd | Ce | 02:0.8:1:4.4 | −8 | 19 |
| 566 | Nd | Pr | 0.99:0.01:1:4.1 | −10 | 31 |
| 567 | Nd | Pr | 0.2:0.8:1:4.2 | −6 | 45 |
| 568 | Nd | Sm | 0.99:0.01:1:4.3 | −6 | 33 |
| 569 | Nd | Sm | 0.2:0.8:1:4.2 | −8 | 30 |
| 570 | Nd | Eu | 0.99:0.01:1:4.1 | −12 | 19 |
| 571 | Nd | Eu | 0.2:0.8:1:4.0 | −10 | 27 |

TABLE 23
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 572 | Nd | Gd | 0.99:0.01:1:3.9 | −8 | 44 |
| 573 | Nd | Gd | 0.2:0.8:1:4.1 | −6 | 37 |
| 574 | Nd | Tb | 0.99:0.01:1:4.0 | −12 | 38 |
| 575 | Nd | Tb | 0.2:0.8:1:3.9 | −13 | 45 |
| 576 | Nd | Dy | 0.99:0.01:1:4.2 | −8 | 28 |
| 577 | Nd | Dy | 0.2:0.8:1:4.1 | −9 | 34 |
| 578 | Nd | Ho | 0.99:0.01:1:4.2 | −8 | 19 |
| 579 | Nd | Ho | 0.2:0.8:1:4.3 | −5 | 30 |
| 580 | Nd | Er | 0.99:0.01:1:4.1 | −8 | 22 |
| 581 | Nd | Er | 0.2:0.8:1:4.2 | −10 | 36 |
| 582 | Nd | Tm | 0.99:0.01:1:4.0 | −6 | 38 |
| 583 | Nd | Tm | 0.2:0.8:1:4.1 | −6 | 44 |
| 584 | Nd | Lu | 0.99:0.01:1:4.2 | −8 | 22 |
| 585 | Nd | Lu | 0.2:0.8:1:4.3 | −12 | 19 |
| 586 | Ce | — | 1:0:1:4.1 | −10 | 31 |
| 587 | Ce | Na | 0.99:0.01:1:3.9 | −8 | 29 |
| 588 | Ce | Na | 0.2:0.8:1:3.8 | −6 | 22 |
| 589 | Ce | K | 0.99:0.01:1:3.8 | −12 | 24 |
| 590 | Ce | K | 0.2:0.8:1:4.0 | −13 | 32 |
| 591 | Ce | Li | 0.99:0.01:1:4.1 | −8 | 29 |
| 592 | Ce | Li | 0.2:0.8:1:3.9 | −9 | 35 |
| 593 | Ce | Zn | 0.99:0.01:1:4.2 | −20 | 48 |
| 594 | Ce | Zn | 0.2:0.8:1:4.0 | −5 | 34 |
| 595 | Ce | Pb | 0.99:0.01:1:4.0 | −12 | 16 |
| 596 | Ce | Pb | 0.2:0.8:1:3.9 | −11 | 28 |
| 597 | Ce | Ba | 0.99:0.01:1:3.9 | −6 | 39 |
| 598 | Ce | Ba | 0.2:0.8:1:4.0 | −25 | 20 |

TABLE 24
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 599 | Ce | Ca | 0.99:0.01:1:4.0 | −18 | 14 |
| 600 | Ce | Ca | 0.2:0.8:1:4.0 | −21 | 22 |
| 601 | Ce | Al | 0.99:0.01:1:3.9 | −14 | 31 |
| 602 | Ce | Al | 0.2:0.8:1:4.2 | −18 | 44 |
| 603 | Ce | Bi | 0.99:0.01:1:4.4 | −8 | 35 |
| 604 | Ce | Bi | 0.2:0.8:1:4.3 | −5 | 30 |
| 605 | Ce | Y | 0.99:0.01:1:4.0 | −8 | 25 |
| 606 | Ce | Y | 0.2:0.8:1:4.2 | −10 | 33 |
| 607 | Ce | La | 0.99:0.01:1:4.1 | −6 | 34 |
| 608 | Ce | La | 0.2:0.8:1:3.9 | −6 | 40 |
| 609 | Ce | Pr | 0.99:0.01:1:3.9 | −8 | 26 |
| 610 | Ce | Pr | 0.2:0.8:1:4.2 | −12 | 38 |
| 611 | Ce | Nd | 0.99:0.01:1:4.1 | −10 | 23 |
| 612 | Ce | Nd | 0.2:0.8:1:4.0 | −8 | 32 |
| 613 | Ce | Sm | 0.99:0.01:1:4.3 | −6 | 15 |
| 614 | Ce | Sm | 0.2:0.8:1:4.2 | −12 | 25 |
| 615 | Ce | Eu | 0.99:0.01:1:4.0 | −13 | 44 |
| 616 | Ce | Eu | 0.2:0.8:1:4.1 | −8 | 22 |
| 617 | Ce | Gd | 0.99:0.01:1:4.0 | −9 | 30 |
| 618 | Ce | Gd | 0.2:0.8:1:4.0 | −20 | 45 |
| 619 | Ce | Tb | 0.99:0.01:1:3.9 | −5 | 23 |
| 620 | Ce | Tb | 0.2:0.8:1:4.2 | −18 | 16 |
| 621 | Ce | Dy | 0.99:0.01:1:4.1 | −8 | 26 |
| 622 | Ce | Dy | 0.2:0.8:1:4.0 | −5 | 30 |
| 623 | Ce | Ho | 0.99:0.01:1:4.2 | −8 | 22 |
| 624 | Ce | Ho | 0.2:0.8:1:4.1 | −5 | 19 |

TABLE 25
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 625 | Ce | Er | 0.99:0.01:1:4.3 | −8 | 24 |
| 626 | Ce | Er | 0.2:0.8:1:3.9 | −10 | 35 |
| 627 | Ce | Tm | 0.99:0.01:1:4.0 | −6 | 30 |
| 628 | Ce | Tm | 0.2:0.8:1:4.2 | −6 | 43 |
| 629 | Ce | Lu | 0.99:0.01:1:4.1 | −8 | 14 |
| 630 | Ce | Lu | 0.2:0.8:1:4.2 | −12 | 40 |
| 631 | Pr | — | 1:0:1:4.1 | −10 | 30 |
| 632 | Pr | Na | 0.99:0.01:1:3.8 | −8 | 45 |
| 633 | Pr | Na | 0.2:0.8:1:3.9 | −6 | 27 |
| 634 | Pr | K | 0.99:0.01:1:3.6 | −12 | 24 |
| 635 | Pr | K | 0.2:0.8:1:3.9 | −13 | 14 |
| 636 | Pr | Li | 0.99:0.01:1:3.9 | −8 | 20 |
| 637 | Pr | Li | 0.2:0.8:1:3.8 | −9 | 19 |
| 638 | Pr | Zn | 0.99:0.01:1:4.1 | −20 | 30 |
| 639 | Pr | Zn | 0.2:0.8:1:4.0 | −5 | 24 |
| 640 | Pr | Pb | 0.99:0.01:1:3.8 | −12 | 22 |
| 641 | Pr | Pb | 0.2:0.8:1:4.0 | −8 | 30 |
| 642 | Pr | Ba | 0.99:0.01:1:4.0 | −8 | 41 |
| 643 | Pr | Ba | 0.2:0.8:1:4.0 | −5 | 29 |
| 644 | Pr | Ca | 0.99:0.01:1:3.9 | −8 | 34 |
| 645 | Pr | Ca | 0.2:0.8:1:3.9 | −10 | 27 |
| 646 | Pr | Al | 0.99:0.01:1:4.2 | −6 | 32 |
| 647 | Pr | Al | 0.2:0.8:1:4.1 | −6 | 19 |
| 648 | Pr | Bi | 0.99:0.01:1:4.3 | −8 | 15 |
| 649 | Pr | Bi | 0.2:0.8:1:4.4 | −12 | 30 |
| 650 | Pr | Y | 0.99:0.01:1:4.2 | −10 | 27 |

TABLE 26
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 651 | Pr | Y | 0.2:0.8:1:4.0 | −8 | 24 |
| 652 | Pr | La | 0.99:0.01:1:4.2 | −6 | 39 |
| 653 | Pr | La | 0.2:0.8:1:4.1 | −12 | 29 |
| 654 | Pr | Ce | 0.99:0.01:1:4.2 | −13 | 30 |
| 655 | Pr | Ce | 0.2:0.8:1:4.2 | −8 | 45 |
| 656 | Pr | Nd | 0.99:0.01:1:4.0 | −9 | 36 |
| 657 | Pr | Nd | 0.2:0.8:1:4.1 | −20 | 24 |
| 658 | Pr | Sm | 0.99:0.01:1:3.9 | −5 | 22 |
| 659 | Pr | Sm | 0.2:0.8:1:4.1 | −18 | 20 |
| 660 | Pr | Eu | 0.99:0.01:1:4.2 | −8 | 34 |
| 661 | Pr | Eu | 0.2:0.8:1:4.1 | −5 | 25 |
| 662 | Pr | Gd | 0.99:0.01:1:4.0 | −8 | 39 |
| 663 | Pr | Gd | 0.2:0.8:1:4.1 | −6 | 25 |
| 664 | Pr | Tb | 0.99:0.01:1:4.0 | −12 | 29 |
| 665 | Pr | Tb | 0.2:0.8:1:4.0 | −16 | 22 |
| 666 | Pr | Dy | 0.99:0.01:1:3.9 | −25 | 24 |
| 667 | Pr | Dy | 0.2:0.8:1:4.1 | −18 | 32 |
| 668 | Pr | Ho | 0.99:0.01:1:4.2 | −5 | 29 |
| 669 | Pr | Ho | 0.2:0.8:1:4.0 | −8 | 35 |
| 670 | Pr | Er | 0.99:0.01:1:4.2 | −5 | 48 |
| 671 | Pr | Er | 0.2:0.8:1:4.1 | −8 | 34 |
| 672 | Pr | Tm | 0.99:0.01:1:3.9 | −10 | 16 |
| 673 | Pr | Tm | 0.2:0.8:1:4.2 | −6 | 28 |
| 674 | Pr | Lu | 0.99:0.01:1:4.2 | −18 | 39 |
| 675 | Pr | Lu | 0.2:0.8:1:4.3 | −20 | 20 |
| 676 | Sm | — | 1:0:1:4.1 | −19 | 14 |
| 677 | Sm | Na | 0.99:0.01:1:3.9 | −16 | 22 |

TABLE 27
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 678 | Sm | Na | 0.2:0.8:1:3.8 | −6 | 31 |
| 679 | Sm | K | 0.99:0.01:1:3.8 | −12 | 44 |
| 680 | Sm | K | 0.2:0.8:1:4.0 | −16 | 35 |
| 681 | Sm | Li | 0.99:0.01:1:4.1 | −25 | 30 |
| 682 | Sm | Li | 0.2:0.8:1:3.9 | −18 | 25 |
| 683 | Sm | Zn | 0.99:0.01:1:4.2 | −5 | 33 |
| 684 | Sm | Zn | 0.2:0.8:1:4.0 | −8 | 34 |
| 685 | Sm | Pb | 0.99:0.01:1:4.0 | −5 | 40 |
| 686 | Sm | Pb | 0.2:0.8:1:3.9 | −8 | 26 |
| 687 | Sm | Ba | 0.99:0.01:1:3.9 | −10 | 38 |
| 688 | Sm | Ba | 0.2:0.8:1:4.0 | −6 | 23 |
| 689 | Sm | Ca | 0.99:0.01:1:4.0 | −6 | 32 |
| 690 | Sm | Ca | 0.2:0.8:1:4.0 | −8 | 38 |
| 691 | Sm | Al | 0.99:0.01:1:3.9 | −12 | 44 |
| 692 | Sm | Al | 0.2:0.8:1:4.2 | −10 | 22 |
| 693 | Sm | Bi | 0.99:0.01:1:4.4 | −8 | 19 |
| 694 | Sm | Bi | 0.2:0.8:1:4.3 | −6 | 31 |
| 695 | Sm | Y | 0.99:0.01:1:4.0 | −12 | 29 |
| 696 | Sm | Y | 0.2:0.8:1:4.2 | −13 | 22 |
| 697 | Sm | La | 0.99:0.01:1:4.1 | −8 | 24 |
| 698 | Sm | La | 0.2:0.8:1:3.9 | −9 | 32 |
| 699 | Sm | Ce | 0.99:0.01:1:3.9 | −20 | 29 |
| 700 | Sm | Ce | 0.2:0.8:1:4.2 | −5 | 35 |
| 701 | Sm | Pr | 0.99:0.01:1:4.1 | −12 | 48 |
| 702 | Sm | Pr | 0.2:0.8:1:4.0 | −8 | 34 |
| 703 | Sm | Nd | 0.99:0.01:1:4.3 | −8 | 16 |

TABLE 28
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 704 | Sm | Nd | 0.2:0.8:1:4.2 | −12 | 28 |
| 705 | Sm | Eu | 0.99:0.01:1:4.0 | −24 | 39 |
| 706 | Sm | Eu | 0.2:0.8:1:4.1 | −17 | 20 |
| 707 | Sm | Gd | 0.99:0.01:1:4.0 | −5 | 14 |
| 708 | Sm | Gd | 0.2:0.8:1:4.0 | −8 | 22 |
| 709 | Sm | Tb | 0.99:0.01:1:3.9 | −5 | 31 |
| 710 | Sm | Tb | 0.2:0.8:1:4.2 | −8 | 44 |
| 711 | Sm | Dy | 0.99:0.01:1:4.1 | −10 | 35 |
| 712 | Sm | Dy | 0.2:0.8:1:4.0 | −6 | 30 |
| 713 | Sm | Ho | 0.99:0.01:1:4.2 | −6 | 25 |
| 714 | Sm | Ho | 0.2:0.8:1:4.1 | −8 | 33 |
| 715 | Sm | Er | 0.99:0.01:1:4.3 | −12 | 34 |
| 716 | Sm | Er | 0.2:0.8:1:3.9 | −10 | 40 |
| 717 | Sm | Tm | 0.99:0.01:1:4.0 | −8 | 26 |
| 718 | Sm | Tm | 0.2:0.8:1:4.2 | −6 | 19 |
| 719 | Sm | Lu | 0.99:0.01:1:4.1 | −12 | 15 |
| 720 | Sm | Lu | 0.2:0.8:1:4.2 | −13 | 30 |
| 721 | Eu | — | 1:0:1:4.1 | −8 | 27 |
| 722 | Eu | Na | 0.99:0.01:1:3.8 | −9 | 24 |
| 723 | Eu | Na | 0.2:0.8:1:3.9 | −20 | 39 |
| 724 | Eu | K | 0.99:0.01:1:3.6 | −5 | 29 |
| 725 | Eu | K | 0.2:0.8:1:3.9 | −12 | 30 |
| 726 | Eu | Li | 0.99:0.01:1:3.9 | −8 | 45 |
| 727 | Eu | Li | 0.2:0.8:1:3.8 | −8 | 36 |
| 728 | Eu | Zn | 0.99:0.01:1:4.1 | −5 | 24 |
| 729 | Eu | Zn | 0.2:0.8:1:4.0 | −8 | 22 |
| 730 | Eu | Pb | 0.99:0.01:1:3.8 | −10 | 20 |

TABLE 29
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 731 | Eu | Pb | 0.2:0.8:1:4.0 | −6 | 34 |
| 732 | Eu | Ba | 0.99:0.01:1:4.0 | −20 | 25 |
| 733 | Eu | Ba | 0.2:0.8:1:4.0 | −25 | 39 |
| 734 | Eu | Ca | 0.99:0.01:1:3.9 | −16 | 25 |
| 735 | Eu | Ca | 0.2:0.8:1:3.9 | −13 | 29 |
| 736 | Eu | Al | 0.99:0.01:1:4.2 | −8 | 22 |
| 737 | Eu | Al | 0.2:0.8:1:4.1 | −6 | 24 |
| 738 | Eu | Bi | 0.99:0.01:1:4.3 | −12 | 32 |
| 739 | Eu | Bi | 0.2:0.8:1:4.4 | −13 | 29 |
| 740 | Eu | Y | 0.99:0.01:1:4.2 | −8 | 35 |
| 741 | Eu | Y | 0.2:0.8:1:4.0 | −9 | 48 |
| 742 | Eu | La | 0.99:0.01:1:4.2 | −20 | 34 |
| 743 | Eu | La | 0.2:0.8:1:4.1 | −5 | 16 |
| 744 | Eu | Ce | 0.99:0.01:1:4.2 | −18 | 28 |
| 745 | Eu | Ce | 0.2:0.8:1:4.2 | −8 | 39 |
| 746 | Eu | Pr | 0.99:0.01:1:4.0 | −5 | 20 |
| 747 | Eu | Pr | 0.2:0.8:1:4.1 | −19 | 14 |
| 748 | Eu | Nd | 0.99:0.01:1:3.9 | −16 | 22 |
| 749 | Eu | Nd | 0.2:0.8:1:4.1 | −25 | 31 |
| 750 | Eu | Sm | 0.99:0.01:1:4.2 | −12 | 44 |
| 751 | Eu | Sm | 0.2:0.8:1:4.1 | −5 | 19 |
| 752 | Eu | Gd | 0.99:0.01:1:4.0 | −8 | 32 |
| 753 | Eu | Gd | 0.2:0.8:1:4.1 | −6 | 15 |
| 754 | Eu | Tb | 0.99:0.01:1:4.0 | −5 | 25 |
| 755 | Eu | Tb | 0.2:0.8:1:4.0 | −8 | 44 |
| 756 | Eu | Dy | 0.99:0.01:1:3.9 | −5 | 22 |

TABLE 30
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 757 | Eu | Dy | 0.2:0.8:1:4.1 | −8 | 30 |
| 758 | Eu | Ho | 0.99:0.01:1:4.2 | −10 | 45 |
| 759 | Eu | Ho | 0.2:0.8:1:4.0 | −6 | 23 |
| 760 | Eu | Er | 0.99:0.01:1:4.2 | −6 | 16 |
| 761 | Eu | Er | 0.2:0.8:1:4.1 | −8 | 26 |
| 762 | Eu | Tm | 0.99:0.01:1:3.9 | −12 | 30 |
| 763 | Eu | Tm | 0.2:0.8:1:4.2 | −10 | 22 |
| 764 | Eu | Lu | 0.99:0.01:1:4.2 | −8 | 19 |
| 765 | Eu | Lu | 0.2:0.8:1:4.3 | −6 | 24 |
| 766 | Gd | — | 1:0:1:4.0 | −12 | 35 |
| 767 | Gd | Na | 0.99:0.01:1:3.6 | −16 | 30 |
| 768 | Gd | Na | 0.2:0.8:1:3.9 | −25 | 43 |
| 769 | Gd | K | 0.99:0.01:1:3.7 | −18 | 14 |
| 770 | Gd | K | 0.2:0.8:1:3.8 | −5 | 40 |
| 771 | Gd | Li | 0.99:0.01:1:3.8 | −8 | 30 |
| 772 | Gd | Li | 0.2:0.8:1:3.6 | −5 | 45 |
| 773 | Gd | Zn | 0.99:0.01:1:4.0 | −8 | 27 |
| 774 | Gd | Zn | 0.2:0.8:1:3.8 | −10 | 24 |
| 775 | Gd | Pb | 0.99:0.01:1:3.6 | −6 | 14 |
| 776 | Gd | Pb | 0.2:0.8:1:3.6 | −6 | 20 |
| 777 | Gd | Ba | 0.99:0.01:1:3.9 | −8 | 19 |
| 778 | Gd | Ba | 0.2:0.8:1:4.0 | −12 | 30 |
| 779 | Gd | Ca | 0.99:0.01:1:3.8 | −10 | 24 |
| 780 | Gd | Ca | 0.2:0.8:1:4.0 | −8 | 22 |
| 781 | Gd | Al | 0.99:0.01:1:4.0 | −6 | 30 |
| 782 | Gd | Al | 0.2:0.8:1:4.1 | −12 | 41 |
| 783 | Gd | Bi | 0.99:0.01:1:4.2 | −13 | 29 |

TABLE 31
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 784 | Gd | Bi | 0.2:0.8:1:4.4 | −8 | 34 |
| 785 | Gd | Y | 0.99:0.01:1:4.2 | −9 | 27 |
| 786 | Gd | Y | 0.2:0.8:1:4.3 | −20 | 32 |
| 787 | Gd | La | 0.99:0.01:1:4.0 | −5 | 19 |
| 788 | Gd | La | 0.2:0.8:1:4.1 | −12 | 15 |
| 789 | Gd | Ce | 0.99:0.01:1:4.2 | −8 | 25 |
| 790 | Gd | Ce | 0.2:0.8:1:4.4 | −8 | 33 |
| 791 | Gd | Pr | 0.99:0.01:1:4.1 | −5 | 34 |
| 792 | Gd | Pr | 0.2:0.8:1:4.2 | −8 | 40 |
| 793 | Gd | Nd | 0.99:0.01:1:4.3 | −10 | 26 |
| 794 | Gd | Nd | 0.2:0.8:1:4.2 | −6 | 19 |
| 795 | Gd | Sm | 0.99:0.01:1:4.1 | −8 | 15 |
| 796 | Gd | Sm | 0.2:0.8:1:4.0 | −5 | 30 |
| 797 | Gd | Eu | 0.99:0.01:1:3.9 | −8 | 27 |
| 798 | Gd | Eu | 0.2:0.8:1:4.1 | −10 | 24 |
| 799 | Gd | Tb | 0.99:0.01:1:4.0 | −6 | 39 |
| 800 | Gd | Tb | 0.2:0.8:1:3.9 | −6 | 29 |
| 801 | Gd | Dy | 0.99:0.01:1:4.2 | −8 | 30 |
| 802 | Gd | Dy | 0.2:0.8:1:4.1 | −12 | 45 |
| 803 | Gd | Ho | 0.99:0.01:1:4.2 | −10 | 36 |
| 804 | Gd | Ho | 0.2:0.8:1:4.3 | −8 | 24 |
| 805 | Gd | Er | 0.99:0.01:1:4.1 | −6 | 22 |
| 806 | Gd | Er | 0.2:0.8:1:4.2 | −12 | 20 |
| 807 | Gd | Tm | 0.99:0.01:1:4.0 | −16 | 34 |
| 808 | Gd | Tm | 0.2:0.8:1:4.1 | −6 | 25 |
| 809 | Gd | Lu | 0.99:0.01:1:4.2 | −12 | 39 |

TABLE 32
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 810 | Gd | Lu | 0.2:0.8:1:4.3 | −16 | 25 |
| 811 | Tb | — | 1:0:1:4.1 | −25 | 29 |
| 812 | Tb | Na | 0.99:0.01:1:3.9 | −18 | 22 |
| 813 | Tb | Na | 0.2:0.8:1:3.8 | −5 | 24 |
| 814 | Tb | K | 0.99:0.01:1:3.8 | −8 | 32 |
| 815 | Tb | K | 0.2:0.8:1:4.0 | −5 | 29 |
| 816 | Tb | Li | 0.99:0.01:1:4.1 | −8 | 35 |
| 817 | Tb | Li | 0.2:0.8:1:3.9 | −10 | 48 |
| 818 | Tb | Zn | 0.99:0.01:1:42 | −6 | 34 |
| 819 | Tb | Zn | 0.2:0.8:1:4.0 | −6 | 16 |
| 820 | Tb | Pb | 0.99:0.01:1:4.0 | −8 | 28 |
| 821 | Tb | Pb | 0.2:0.8:1:3.9 | −12 | 39 |
| 822 | Tb | Ba | 0.99:0.01:1:3.9 | −10 | 20 |
| 823 | Tb | Ba | 0.2:0.8:1:4.0 | −8 | 14 |
| 824 | Tb | Ca | 0.99:0.01:1:4.0 | −8 | 22 |
| 825 | Tb | Ca | 0.2:0.8:1:4.0 | −23 | 31 |
| 826 | Tb | Al | 0.99:0.01:1:3.9 | −27 | 44 |
| 827 | Tb | Al | 0.2:0.8:1:4.2 | −18 | 19 |
| 828 | Tb | Bi | 0.99:0.01:1:4.4 | −15 | 32 |
| 829 | Tb | Bi | 0.2:0.8:1:4.3 | −8 | 15 |
| 830 | Tb | Y | 0.99:0.01:1:4.0 | −12 | 26 |
| 831 | Tb | Y | 0.2:0.8:1:4.2 | −10 | 30 |
| 832 | Tb | La | 0.99:0.01:1:4.1 | −19 | 22 |
| 833 | Tb | La | 0.2:0.8:1:3.9 | −25 | 19 |
| 834 | Tb | Ce | 0.99:0.01:1:3.9 | −14 | 24 |
| 835 | Tb | Ce | 0.2:0.8:1:4.2 | −12 | 35 |

TABLE 33
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 836 | Tb | Pr | 0.99:0.01:1:4.1 | −5 | 30 |
| 837 | Tb | Pr | 0.2:0.8:1:4.0 | −8 | 43 |
| 838 | Tb | Nd | 0.99:0.01:1:4.3 | −6 | 14 |
| 839 | Tb | Nd | 0.2:0.8:1:4.2 | −9 | 40 |
| 840 | Tb | Sm | 0.99:0.01:1:4.0 | −12 | 30 |
| 841 | Tb | Sm | 0.2:0.8:1:4.1 | −5 | 45 |
| 842 | Tb | Eu | 0.99:0.01:1:4.0 | −21 | 27 |
| 843 | Tb | Eu | 0.2:0.8:1:4.0 | −20 | 24 |
| 844 | Tb | Gd | 0.99:0.01:1:3.9 | −5 | 14 |
| 845 | Tb | Gd | 0.2:0.8:1:4.2 | −8 | 20 |
| 846 | Tb | Dy | 0.99:0.01:1:4.1 | −12 | 19 |
| 847 | Tb | Dy | 0.2:0.8:1:4.0 | −20 | 30 |
| 848 | Tb | Ho | 0.99:0.01:1:4.2 | −8 | 24 |
| 849 | Tb | Ho | 0.2:0.8:1:4.1 | −5 | 22 |
| 850 | Tb | Er | 0.99:0.01:1:4.3 | −8 | 30 |
| 851 | Tb | Er | 0.2:0.8:1:3.9 | −10 | 41 |
| 852 | Tb | Tm | 0.99:0.01:1:4.0 | −6 | 29 |
| 853 | Tb | Tm | 0.2:0.8:1:4.2 | −6 | 34 |
| 854 | Tb | Lu | 0.99:0.01:1:4.1 | −8 | 27 |
| 855 | Tb | Lu | 0.2:0.8:1:4.2 | −18 | 32 |
| 856 | Dy | — | 1:0:1:4.0 | −20 | 19 |
| 857 | Dy | Na | 0.99:0.01:1:3.6 | −18 | 15 |
| 858 | Dy | Na | 0.2:0.8:1:3.9 | −5 | 25 |
| 859 | Dy | K | 0.99:0.01:1:3.7 | −8 | 30 |
| 860 | Dy | K | 0.2:0.8:1:3.8 | −6 | 43 |
| 861 | Dy | Li | 0.99:0.01:1:3.8 | −9 | 14 |

TABLE 34
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 862 | Dy | Li | 0.2:0.8:1:3.6 | −12 | 40 |
| 863 | Dy | Zn | 0.99:0.01:1:4.0 | −5 | 30 |
| 864 | Dy | Zn | 0.2:0.8:1:3.8 | −21 | 45 |
| 865 | Dy | Pb | 0.99:0.01:1:3.6 | −15 | 27 |
| 866 | Dy | Pb | 0.2:0.8:1:3.6 | −18 | 24 |
| 867 | Dy | Ba | 0.99:0.01:1:3.9 | −12 | 14 |
| 868 | Dy | Ba | 0.2:0.8:1:4.0 | −5 | 20 |
| 869 | Dy | Ca | 0.99:0.01:1:3.8 | −8 | 19 |
| 870 | Dy | Ca | 0.2:0.8:1:4.0 | −6 | 30 |
| 871 | Dy | Al | 0.99:0.01:1:4.0 | −9 | 24 |
| 872 | Dy | Al | 0.2:0.8:1:4.1 | −12 | 22 |
| 873 | Dy | Bi | 0.99:0.01:1:4.2 | −5 | 30 |
| 874 | Dy | Bi | 0.2:0.8:1:4.4 | −21 | 41 |
| 875 | Dy | Y | 0.99:0.01:1:4.2 | −20 | 29 |
| 876 | Dy | Y | 0.2:0.8:1:4.3 | −5 | 34 |
| 877 | Dy | La | 0.99:0.01:1:4.0 | −8 | 27 |
| 878 | Dy | La | 0.2:0.8:1:4.1 | −12 | 32 |
| 879 | Dy | Ce | 0.99:0.01:1:4.2 | −20 | 19 |
| 880 | Dy | Ce | 0.2:0.8:1:4.4 | −8 | 15 |
| 881 | Dy | Pr | 0.99:0.01:1:4.1 | −5 | 25 |
| 882 | Dy | Pr | 0.2:0.8:1:4.2 | −8 | 33 |
| 883 | Dy | Nd | 0.99:0.01:1:4.3 | −10 | 34 |
| 884 | Dy | Nd | 0.2:0.8:1:4.2 | −6 | 30 |
| 885 | Dy | Sm | 0.99:0.01:1:4.1 | −18 | 22 |
| 886 | Dy | Sm | 0.2:0.8:1:4.0 | −5 | 19 |
| 887 | Dy | Eu | 0.99:0.01:1:3.9 | −8 | 24 |

TABLE 35
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 888 | Dy | Eu | 0.2:0.8:1:4.1 | −6 | 35 |
| 889 | Dy | Gd | 0.99:0.01:1:4.0 | −9 | 30 |
| 890 | Dy | Gd | 0.2:0.8:1:3.9 | −12 | 43 |
| 891 | Dy | Tb | 0.99:0.01:1:4.2 | −5 | 14 |
| 892 | Dy | Tb | 0.2:0.8:1:4.1 | −21 | 40 |
| 893 | Dy | Ho | 0.99:0.01:1:4.2 | −18 | 30 |
| 894 | Dy | Ho | 0.2:0.8:1:4.3 | −20 | 45 |
| 895 | Dy | Er | 0.99:0.01:1:4.1 | −18 | 27 |
| 896 | Dy | Er | 0.2:0.8:1:4.2 | −5 | 24 |
| 897 | Dy | Tm | 0.99:0.01:1:4.0 | −8 | 14 |
| 898 | Dy | Tm | 0.2:0.8:1:4.1 | −6 | 20 |
| 899 | Dy | Lu | 0.99:0.01:1:4.2 | −9 | 19 |
| 900 | Dy | Lu | 0.2:0.8:1:4.3 | −12 | 30 |
| 901 | Ho | — | 1:0:1:4.1 | −5 | 24 |
| 902 | Ho | Na | 0.99:0.01:1:3.8 | −21 | 22 |
| 903 | Ho | Na | 0.2:0.8:1:3.9 | −15 | 30 |
| 904 | Ho | K | 0.99:0.01:1:3.6 | −18 | 41 |
| 905 | Ho | K | 0.2:0.8:1:3.9 | −12 | 29 |
| 906 | Ho | Li | 0.99:0.01:1:3.9 | −5 | 34 |
| 907 | Ho | Li | 0.2:0.8:1:3.8 | −18 | 27 |
| 908 | Ho | Zn | 0.99:0.01:1:4.1 | −20 | 32 |
| 909 | Ho | Zn | 0.2:0.8:1:4.0 | −12 | 19 |
| 910 | Ho | Pb | 0.99:0.01:1:3.8 | −5 | 15 |
| 911 | Ho | Pb | 0.2:0.8:1:4.0 | −8 | 25 |
| 912 | Ho | Ba | 0.99:0.01:1:4.0 | −6 | 30 |
| 913 | Ho | Ba | 0.2:0.8:1:4.0 | −9 | 43 |

TABLE 36
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 914 | Ho | Ca | 0.99:0.01:1:3.9 | −12 | 14 |
| 915 | Ho | Ca | 0.2:0.8:1:3.9 | −5 | 40 |
| 916 | Ho | Al | 0.99:0.01:1:4.2 | −9 | 30 |
| 917 | Ho | Al | 0.2:0.8:1:4.1 | −12 | 45 |
| 918 | Ho | Bi | 0.99:0.01:1:4.3 | −5 | 27 |
| 919 | Ho | Bi | 0.2:0.8:1:4.4 | −5 | 24 |
| 920 | Ho | Y | 0.99:0.01:1:4.2 | −8 | 14 |
| 921 | Ho | Y | 0.2:0.8:1:4.0 | −12 | 20 |
| 922 | Ho | La | 0.99:0.01:1:42 | −20 | 19 |
| 923 | Ho | La | 0.2:0.8:1:4.1 | −8 | 30 |
| 924 | Ho | Ce | 0.99:0.01:1:4.2 | −5 | 22 |
| 925 | Ho | Ce | 0.2:0.8:1:4.2 | −8 | 19 |
| 926 | Ho | Pr | 0.99:0.01:1:4.0 | −10 | 24 |
| 927 | Ho | Pr | 0.2:0.8:1:4.1 | −6 | 35 |
| 928 | Ho | Nd | 0.99:0.01:1:3.9 | −18 | 30 |
| 929 | Ho | Nd | 0.2:0.8:1:4.1 | −5 | 43 |
| 930 | Ho | Sm | 0.99:0.01:1:4.2 | −8 | 14 |
| 931 | Ho | Sm | 0.2:0.8:1:4.1 | −6 | 40 |
| 932 | Ho | Eu | 0.99:0.01:1:4.0 | −9 | 30 |
| 933 | Ho | Eu | 0.2:0.8:1:4.1 | −12 | 45 |
| 934 | Ho | Gd | 0.99:0.01:1:4.0 | −5 | 27 |
| 935 | Ho | Gd | 0.2:0.8:1:4.0 | −21 | 24 |
| 936 | Ho | Tb | 0.99:0.01:1:3.9 | −18 | 14 |
| 937 | Ho | Tb | 0.2:0.8:1:4.1 | −20 | 20 |
| 938 | Ho | Dy | 0.99:0.01:1:4.2 | −18 | 19 |
| 939 | Ho | Dy | 0.2:0.8:1:4.0 | −5 | 30 |

TABLE 37
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 940 | Ho | Er | 0.99:0.01:1:4.2 | −8 | 24 |
| 941 | Ho | Er | 0.2:0.8:1:4.1 | −6 | 22 |
| 942 | Ho | Tm | 0.99:0.01:1:3.9 | −9 | 30 |
| 943 | Ho | Tm | 0.2:0.8:1:4.2 | −12 | 41 |
| 944 | Ho | Lu | 0.99:0.01:1:4.2 | −5 | 29 |
| 945 | Ho | Lu | 0.2:0.8:1:4.3 | −8 | 34 |
| 946 | Er | — | 1:0:1:4.0 | −12 | 27 |
| 947 | Er | Na | 0.99:0.01:1:3.6 | −8 | 32 |
| 948 | Er | Na | 0.2:0.8:1:3.9 | −5 | 19 |
| 949 | Er | K | 0.99:0.01:1:3.7 | −8 | 15 |
| 950 | Er | K | 0.2:0.8:1:3.8 | −10 | 25 |
| 951 | Er | Li | 0.99:0.01:1:3.8 | −6 | 30 |
| 952 | Er | Li | 0.2:0.8:1:3.6 | −6 | 43 |
| 953 | Er | Zn | 0.99:0.01:1:4.0 | −8 | 14 |
| 954 | Er | Zn | 0.2:0.8:1:3.8 | −12 | 40 |
| 955 | Er | Pb | 0.99:0.01:1:3.6 | −10 | 30 |
| 956 | Er | Pb | 0.2:0.8:1:3.6 | −8 | 45 |
| 957 | Er | Ba | 0.99:0.01:1:3.9 | −8 | 27 |
| 958 | Er | Ba | 0.2:0.8:1:4.0 | −23 | 24 |
| 959 | Er | Ca | 0.99:0.01:1:3.8 | −27 | 14 |
| 960 | Er | Ca | 0.2:0.8:1:4.0 | −18 | 20 |
| 961 | Er | Al | 0.99:0.01:1:4.0 | −15 | 32 |
| 962 | Er | Al | 0.2:0.8:1:4.1 | −8 | 19 |
| 963 | Er | Bi | 0.99:0.01:1:4.2 | −12 | 15 |
| 964 | Er | Bi | 0.2:0.8:1:4.4 | −10 | 25 |
| 965 | Er | Y | 0.99:0.01:1:4.2 | −19 | 30 |

TABLE 38
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 966 | Er | Y | 0.2:0.8:1:4.3 | −25 | 43 |
| 967 | Er | La | 0.99:0.01:1:4.0 | −14 | 14 |
| 968 | Er | La | 0.2:0.8:1:4.1 | −12 | 40 |
| 969 | Er | Ce | 0.99:0.01:1:4.2 | −5 | 30 |
| 970 | Er | Ce | 0.2:0.8:1:4.4 | −8 | 45 |
| 971 | Er | Pr | 0.99:0.01:1:4.1 | −6 | 27 |
| 972 | Er | Pr | 0.2:0.8:1:4.2 | −9 | 24 |
| 973 | Er | Nd | 0.99:0.01:1:4.3 | −8 | 14 |
| 974 | Er | Nd | 0.2:0.8:1:4.2 | −5 | 20 |
| 975 | Er | Sm | 0.99:0.01:1:4.1 | −8 | 32 |
| 976 | Er | Sm | 0.2:0.8:1:4.0 | −10 | 19 |
| 977 | Er | Eu | 0.99:0.01:1:3.9 | −12 | 15 |
| 978 | Er | Eu | 0.2:0.8:1:4.1 | −5 | 25 |
| 979 | Er | Gd | 0.99:0.01:1:4.0 | −18 | 30 |
| 980 | Er | Gd | 0.2:0.8:1:3.9 | −20 | 43 |
| 981 | Er | Tb | 0.99:0.01:1:4.2 | −12 | 14 |
| 982 | Er | Tb | 0.2:0.8:1:4.1 | −5 | 40 |
| 983 | Er | Dy | 0.99:0.01:1:4.2 | −8 | 30 |
| 984 | Er | Dy | 0.2:0.8:1:4.3 | −6 | 45 |
| 985 | Er | Ho | 0.99:0.01:1:4.1 | −9 | 27 |
| 986 | Er | Ho | 0.2:0.8:1:4.2 | −12 | 24 |
| 987 | Er | Tm | 0.99:0.01:1:4.0 | −5 | 14 |
| 988 | Er | Tm | 0.2:0.8:1:4.1 | −9 | 20 |
| 989 | Er | Lu | 0.99:0.01:1:4.2 | −12 | 32 |
| 990 | Er | Lu | 0.2:0.8:1:4.3 | −5 | 19 |
| 991 | Tm | — | 1:0:1:4.1 | −5 | 15 |

TABLE 39
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 992 | Tm | Na | 0.99:0.01:1:3.9 | −8 | 25 |
| 993 | Tm | Na | 0.2:0.8:1:3.8 | −12 | 30 |
| 994 | Tm | K | 0.99:0.01:1:3.8 | −20 | 43 |
| 995 | Tm | K | 0.2:0.8:1:4.0 | −8 | 14 |
| 996 | Tm | Li | 0.99:0.01:1:4.1 | −5 | 24 |
| 997 | Tm | Li | 0.2:0.8:1:3.9 | −8 | 35 |
| 998 | Tm | Zn | 0.99:0.01:1:4.2 | −10 | 30 |
| 999 | Tm | Zn | 0.2:0.8:1:4.0 | −9 | 43 |
| 1000 | Tm | Pb | 0.99:0.01:1:4.0 | −12 | 14 |
| 1001 | Tm | Pb | 0.2:0.8:1:3.9 | −5 | 40 |
| 1002 | Tm | Ba | 0.99:0.01:1:3.9 | −21 | 30 |
| 1003 | Tm | Ba | 0.2:0.8:1:4.0 | −18 | 45 |
| 1004 | Tm | Ca | 0.99:0.01:1:4.0 | −20 | 27 |
| 1005 | Tm | Ca | 0.2:0.8:1:4.0 | −18 | 24 |
| 1006 | Tm | Al | 0.99:0.01:1:3.9 | −5 | 14 |
| 1007 | Tm | Al | 0.2:0.8:1:4.2 | −8 | 20 |
| 1008 | Tm | Bi | 0.99:0.01:1:4.4 | −6 | 19 |
| 1009 | Tm | Bi | 0.2:0.8:1:4.3 | −9 | 30 |
| 1010 | Tm | Y | 0.99:0.01:1:4.0 | −12 | 24 |
| 1011 | Tm | Y | 0.2:0.8:1:4.2 | −5 | 22 |
| 1012 | Tm | La | 0.99:0.01:1:4.1 | −21 | 30 |
| 1013 | Tm | La | 0.2:0.8:1:3.9 | −15 | 41 |
| 1014 | Tm | Ce | 0.99:0.01:1:3.9 | −18 | 29 |
| 1015 | Tm | Ce | 0.2:0.8:1:4.2 | −12 | 34 |
| 1016 | Tm | Pr | 0.99:0.01:1:4.1 | −5 | 27 |
| 1017 | Tm | Pr | 0.2:0.8:1:4.0 | −18 | 32 |

TABLE 40
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 1018 | Tm | Nd | 0.99:0.01:1:4.3 | −20 | 19 |
| 1019 | Tm | Nd | 0.2:0.8:1:4.2 | −12 | 15 |
| 1020 | Tm | Sm | 0.99:0.01:1:4.0 | −5 | 25 |
| 1021 | Tm | Sm | 0.2:0.8:1:4.1 | −8 | 30 |
| 1022 | Tm | Eu | 0.99:0.01:1:4.0 | −6 | 43 |
| 1023 | Tm | Eu | 0.2:0.8:1:4.0 | −9 | 14 |
| 1024 | Tm | Gd | 0.99:0.01:1:3.9 | −12 | 40 |
| 1025 | Tm | Gd | 0.2:0.8:1:4.2 | −9 | 30 |
| 1026 | Tm | Tb | 0.99:0.01:1:4.1 | −12 | 45 |
| 1027 | Tm | Tb | 0.2:0.8:1:4.0 | −5 | 27 |
| 1028 | Tm | Dy | 0.99:0.01:1:4.2 | −21 | 24 |
| 1029 | Tm | Dy | 0.2:0.8:1:4.1 | −18 | 14 |
| 1033 | Tm | Ho | 0.99:0.01:1:4.3 | −10 | 20 |
| 1031 | Tm | Ho | 0.2:0.8:1:3.9 | −12 | 19 |
| 1032 | Tm | Er | 0.99:0.01:1:4.0 | −5 | 19 |
| 1033 | Tm | Er | 0.2:0.8:1:4.2 | −18 | 30 |
| 1034 | Tm | Lu | 0.99:0.01:1:4.1 | −20 | 24 |
| 1035 | Tm | Lu | 0.2:0.8:1:4.2 | −12 | 22 |
| 1036 | Lu | — | 1:0:1:4.0 | −5 | 30 |
| 1037 | Lu | Na | 0.99:0.01:1:3.6 | −8 | 41 |
| 1038 | Lu | Na | 0.2:0.8:1:3.9 | −6 | 29 |
| 1039 | Lu | K | 0.99:0.01:1:3.7 | −9 | 34 |
| 1040 | Lu | K | 0.2:0.8:1:3.8 | −12 | 27 |
| 1041 | Lu | Li | 0.99:0.01:1:3.8 | −5 | 32 |
| 1042 | Lu | Li | 0.2:0.8:1:3.6 | −9 | 19 |
| 1043 | Lu | Zn | 0.99:0.01:1:4.0 | −12 | 15 |

TABLE 41
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 1044 | Lu | Zn | 0.2:0.8:1:3.8 | −5 | 25 |
| 1045 | Lu | Pb | 0.99:0.01:1:3.6 | −5 | 30 |
| 1046 | Lu | Pb | 0.2:0.8:1:3.6 | −8 | 43 |
| 1047 | Lu | Ba | 0.99:0.01:1:3.9 | −12 | 14 |
| 1048 | Lu | Ba | 0.2:0.8:1:4.0 | −20 | 40 |
| 1049 | Lu | Ca | 0.99:0.01:1:3.8 | −8 | 30 |
| 1050 | Lu | Ca | 0.2:0.8:1:4.0 | −23 | 45 |
| 1051 | Lu | Al | 0.99:0.01:1:4.0 | −27 | 27 |
| 1052 | Lu | Al | 0.2:0.8:1:4.1 | −18 | 24 |
| 1053 | Lu | Bi | 0.99:0.01:1:4.2 | −15 | 14 |
| 1054 | Lu | Bi | 0.2:0.8:1:4.4 | −8 | 20 |
| 1055 | Lu | Y | 0.99:0.01:1:4.2 | −12 | 32 |
| 1056 | Lu | Y | 0.2:0.8:1:4.3 | −10 | 19 |
| 1057 | Lu | La | 0.99:0.01:1:4.0 | −19 | 15 |
| 1058 | Lu | La | 0.2:0.8:1:4.1 | −5 | 25 |
| 1059 | Lu | Ce | 0.99:0.01:1:4.2 | −8 | 30 |
| 1060 | Lu | Ce | 0.2:0.8:1:4.4 | −6 | 43 |
| 1061 | Lu | Pr | 0.99:0.01:1:4.1 | −9 | 14 |
| 1062 | Lu | Pr | 0.2:0.8:1:4.2 | −12 | 30 |
| 1063 | Lu | Nd | 0.99:0.01:1:4.3 | −9 | 43 |
| 1064 | Lu | Nd | 0.2:0.8:1:4.2 | −12 | 14 |
| 1065 | Lu | Sm | 0.99:0.01:1:4.1 | −5 | 40 |
| 1066 | Lu | Sm | 0.2:0.8:1:4.0 | −21 | 30 |
| 1067 | Lu | Eu | 0.99:0.01:1:3.9 | −18 | 45 |
| 1068 | Lu | Eu | 0.2:0.8:1:4.1 | −10 | 27 |
| 1069 | Lu | Gd | 0.99:0.01:1:4.0 | −12 | 24 |

TABLE 42
(Ln₁₋ₓMₓ)₂NiO_{y}

| | | | | | Electrical |
|---|---|---|---|---|---|
| | | | | Seebeck coefficient | resistivity |
| | | | | at 700° C. | at 700° C. |
| No. | Ln | M | 0.5Ln:0.5M:Ni:O | (μVK⁻¹) | (mΩcm) |
| 1070 | Lu | Gd | 0.2:0.8:1:3.9 | −5 | 14 |
| 1071 | Lu | Tb | 0.99:0.01:1:4.2 | −18 | 20 |
| 1072 | Lu | Tb | 0.2:0.8:1:4.1 | −20 | 19 |
| 1073 | Lu | Dy | 0.99:0.01:1:4.2 | −12 | 19 |
| 1074 | Lu | Dy | 0.2:0.8:1:4.3 | −5 | 30 |
| 1075 | Lu | Ho | 0.99:0.01:1:4.1 | −8 | 24 |
| 1076 | Lu | Ho | 0.2:0.8:1:4.2 | −6 | 22 |
| 1077 | Lu | Er | 0.99:0.01:1:4.0 | −9 | 30 |
| 1078 | Lu | Er | 0.2:0.8:1:4.1 | −5 | 41 |
| 1079 | Lu | Tm | 0.99:0.01:1:4.2 | −8 | 29 |
| 1080 | Lu | Tm | 0.2:0.8:1:4.3 | −12 | 34 |

1. A complex oxide having a composition represented by the formula Ln1-xMxNiOy; wherein Ln is a lanthanide, M is at least one element selected from the group consisting of Na, K, Li, Zn, Pb, Ba, Ca, Al, Bi, and rare earth elements being not the same as Ln; and 0≦x≦0.8; and 2.7≦y≦3.3, the complex oxide having a negative Seebeck coefficient at 100° C. or higher.

2. A complex oxide having a composition represented by the formula Ln1-xMxNiOy; wherein Ln is a lanthanide, M is at least one element selected from the group consisting of Na, K, Li, Zn, Pb, Ba, Ca, Al, Bi, and rare earth elements being not the same as Ln; 0≦x≦0.8; and 2.7≦y≦3.3, the complex oxide having an electrical resistivity of 1 Ωcm or less at 100° C. or higher.

3. A complex oxide having a composition represented by the formula (Ln1-xMx)2NiOy; wherein Ln is a lanthanide, M is at least one element selected from the group consisting of Na, K, Li, Zn, Pb, Ba, Ca, Al, Bi, and rare earth elements being not the same as Ln; 0≦x≦0.8; and 3.6≦y≦4.4, the complex oxide having a negative Seebeck coefficient at 100° C. or higher.

4. A complex oxide having a composition represented by the formula (Ln1-xMx)2NiOy; wherein Ln is a lanthanide, M is at least one element selected from the group consisting of Na, K, Li, Zn, Pb, Ba, Ca, Al, Bi, and rare earth elements being not the same as Ln; 0≦x≦0.8, and 3.6≦y≦4.4, the complex oxide having an electrical resistivity of 1 Ωcm or less at 100° C. or higher.

5. An n-type thermoelectric material comprising the complex oxide of claim 1.

6. A thermoelectric module comprising the n-type thermoelectric material of claim 5.
